(19) United States
(12) Patent Application Publication
(10) Pub. No.: US 2025/0212451 A1
(43) Pub. Date: Jun. 26, 2025

(54) VERTICAL SEMICONDUCTOR DEVICE WITH CONTINUOUS GATE LENGTH AND METHOD OF MANUFACTURING THE SAME, AND ELECTRONIC APPARATUS

(71) Applicant: INSTITUTE OF MICROELECTRONICS, CHINESE ACADEMY OF SCIENCES, Beijing (CN)

(72) Inventor: Huilong ZHU, Poughkeepsie, NY (US)

(21) Appl. No.: 18/720,929

(22) PCT Filed: May 23, 2023
(86) PCT No.: PCT/CN2023/095762

§ 371 Date: Jun. 17, 2024

(30) Foreign Application Priority Data
Apr. 20, 2023 (CN) 202310431478.9

(51) Int. Cl. H10D 30/63; H10D 30/01; H10D 30/43; H10D 62/10; H10D 62/13; H10D 62/17; H10D 64/23; H10D 64/27

(52) U.S. Cl. CPC H10D 30/63; H10D 30/025; H10D 30/026; H10D 30/43; H10D 62/102; H10D 62/121; H10D 62/122; H10D 62/124; H10D 62/151; H10D 62/292; H10D 62/364; H10D 64/2527; H10D 64/518; H10D 30/023; H10D 64/513

(57) ABSTRACT

A vertical semiconductor device with a continuous gate length and a method of manufacturing the same, and an electronic apparatus including the same. The semiconductor device includes: a semiconductor base on a substrate; first and second vertical channel portions on the semiconductor base, where the first and second vertical channel portions are vertical relative to the substrate, protrude from the semiconductor base, are spaced apart from in a first direction and self-aligned with each other, and the semiconductor base extends continuously between the first and second vertical channel portions; a first source/drain portion and a second source/drain portion on the first vertical channel portion and the second vertical channel portion, respectively; and a gate stack at least partially on the first vertical channel portion, the semiconductor base, and the second vertical channel portion to define a continuous channel between the first source/drain portion and the second source/drain portion.

### CROSS REFERENCE TO RELATED APPLICATION(S)

This application is a Section 371 National Stage Application of International Application No. PCT/CN2023/095762, filed on May 23, 2023, which claims priority to Chinese Patent Application No. 202310431478.9, filed on Apr. 20, 2023 and entitled “VERTICAL SEMICONDUCTOR DEVICE WITH CONTINUOUS GATE LENGTH AND METHOD OF MANUFACTURING THE SAME, AND ELECTRONIC APPARATUS”, the entire content of which is incorporated herein in its entirety by reference.

### TECHNICAL FIELD

The present disclosure relates to a field of semiconductors, and in particular to a vertical semiconductor device with a continuous gate length, a method of manufacturing a vertical semiconductor device with a continuous gate length, and an electronic apparatus including the semiconductor device.

### BACKGROUND

With the continuous miniaturization of semiconductor devices such as the metal oxide semiconductor field-effect transistor (MOSFET), devices with various structures such as the fin field-effect transistor (FinFET), the multi-bridge channel field-effect transistor (MBCFET), and the vertical nanosheet or nanowire field-effect transistor are proposed. However, these devices are still limited in certain aspects. For example, input/output (I/O) devices or analog devices require longer or continuous gate lengths, while it is difficult for vertical nanosheet or nanowire devices to have continuous gate lengths.

### SUMMARY

The present disclosure provides a vertical semiconductor device with a continuous gate length, a method of manufacturing a vertical semiconductor device with a continuous gate length, and an electronic apparatus including the semiconductor device.

According to an aspect of the present disclosure, a semiconductor device is provided, including: a semiconductor base on a substrate; a first vertical channel portion and a second vertical channel portion on the semiconductor base, where the first vertical channel portion and the second vertical channel portion are vertical relative to the substrate, protrude from the semiconductor base, are spaced apart from each other in a first direction, and are self-aligned with each other, and the semiconductor base extends continuously between the first vertical channel portion and the second vertical channel portion; a first source/drain portion and a second source/drain portion on the first vertical channel portion and the second vertical channel portion, respectively; and a gate stack, where the gate stack is at least partially provided on the first vertical channel portion, the semiconductor base, and the second vertical channel portion, so as to define a continuous channel between the first source/drain portion and the second source/drain portion.

According to another aspect of the present disclosure, a method of manufacturing a semiconductor device is provided, including: providing, on a substrate, a stack of a first material layer, a second material layer, and a third material layer; patterning the stack as a ridge, where the ridge includes first and second sidewalls extending in a first direction and opposite in a second direction intersecting with the first direction, as well as third and fourth sidewalls extending in the second direction and opposite in the first direction; recessing, at the third and fourth sidewalls, a sidewall of the second material layer laterally relative to a sidewall of the first material layer and a sidewall of the third material layer, so as to define a first recess portion; forming a channel layer on a surface of the second material layer exposed by the first recess portion; forming a first position retaining layer in a remaining space of the first recess portion; further patterning the ridge to form fifth and sixth sidewalls extending in the second direction and opposite in the first direction, so that the second material layer is exposed at the fifth and sixth sidewalls, where the first material layer extends continuously in the first direction between the channel layer formed at the third sidewall and the channel layer formed at the fourth sidewall; removing the second material layer at the fifth and sixth sidewalls; forming a second position retaining layer in a space released due to a removal of the second material layer; forming a source/drain portion in the third material layer; forming an isolation layer on the substrate, where the isolation layer exposes a part of the first material layer extending between the channel layer formed at the third sidewall and the channel layer formed at the fourth sidewall; removing the first position retaining layer and the second position retaining layer; and forming a gate stack on the isolation layer, where the gate stack has a part embedded in a space left due to a removal of the first position retaining layer and the second position retaining layer.

According to another aspect of the present disclosure, an electronic apparatus is provided, including the above-described semiconductor device.

### BRIEF DESCRIPTION OF THE DRAWINGS

The above and other objects, features, and advantages of the present disclosure will become clear through following description on embodiments of the present disclosure with reference to accompanying drawings, in which:

FIGS. 1 to 22(b) show schematic diagrams of some stages in a process of manufacturing a semiconductor device according to an embodiment of the present disclosure;

FIGS. 23 to 33(b) show schematic diagrams of some stages in a process of manufacturing a semiconductor device according to another embodiment of the present disclosure; and

FIGS. 34(a) and 34(b) show schematic diagrams of semiconductor devices according to embodiments of the present disclosure;

in the accompanying drawings:

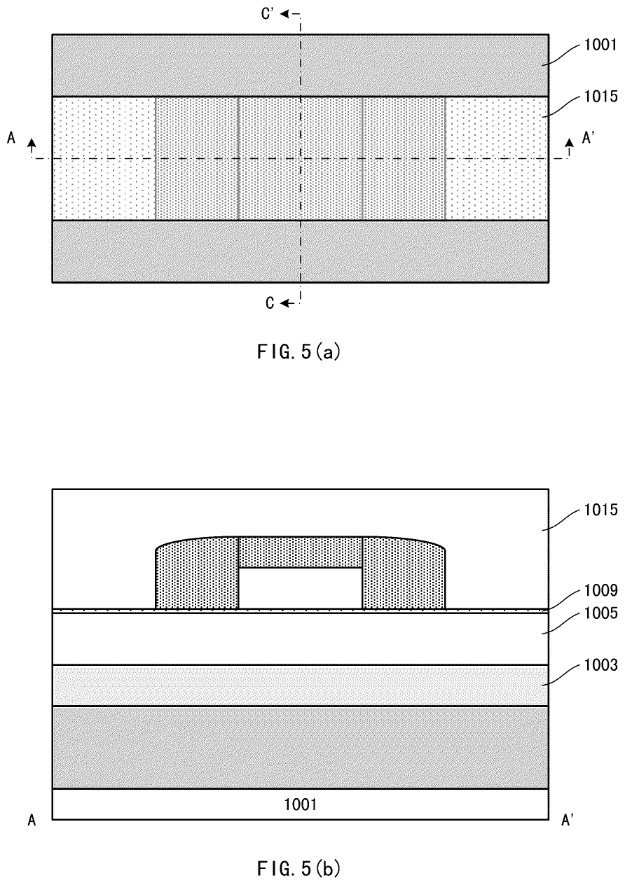

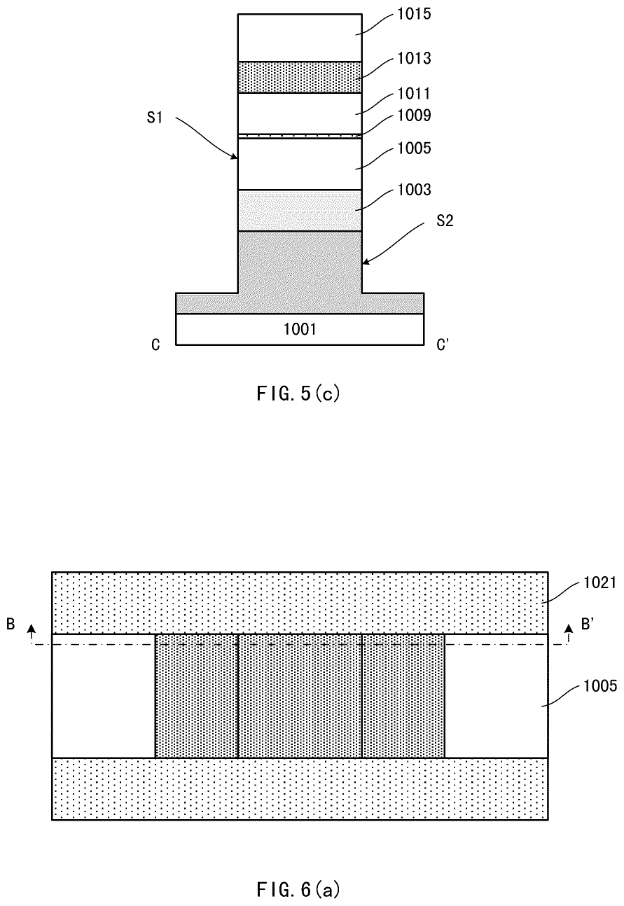

FIGS. 5(a), 6(a), 19(a), 20(a), 20(b), 21(a), 25(a) and 26(a) are top views;

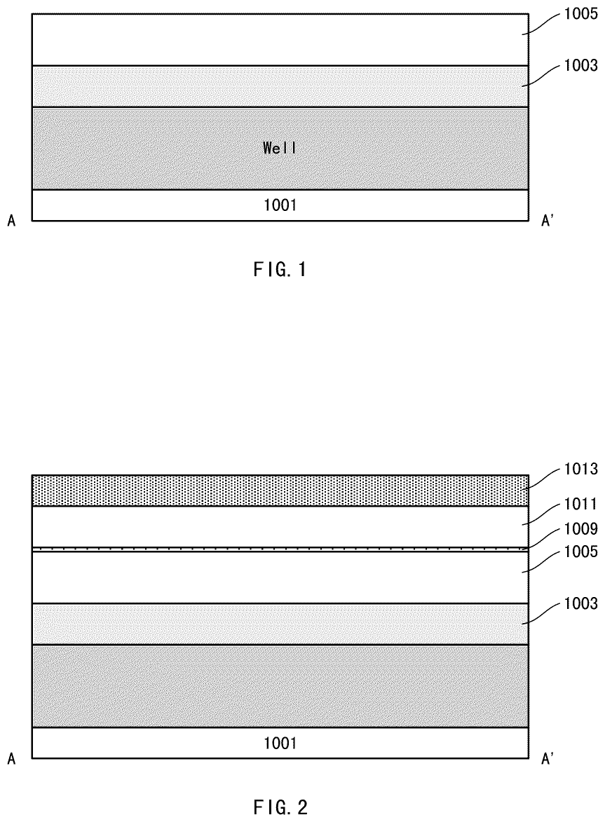

FIGS. 1 to 4, 5(b), 6(b), 7 to 13, 14(a), 14(b), 15(a), 15(b), 16(a), 16(b), 17, 18, 19(b), 19(c), 21(b), 21(c), 22(a), 22(b), 23, 24, 25(b), 26(b), 27(a), 27(b), 28(a), 28(b), 29(a), 29(b), 30(a), 30(b), 31(a), 31(b), 32(a), 32(b), 33(a), 33(b), 34(a) and 34(b) are cross-sectional views taken along line AA′;

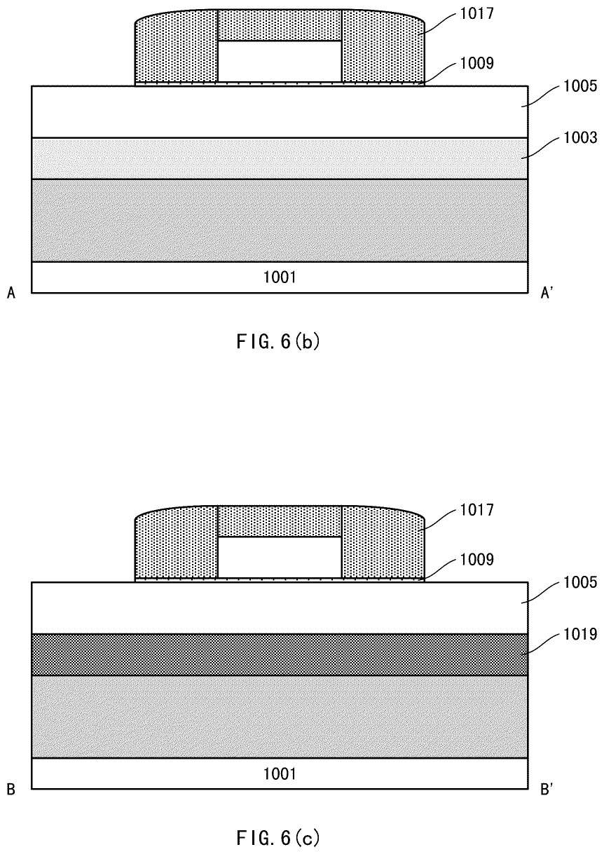

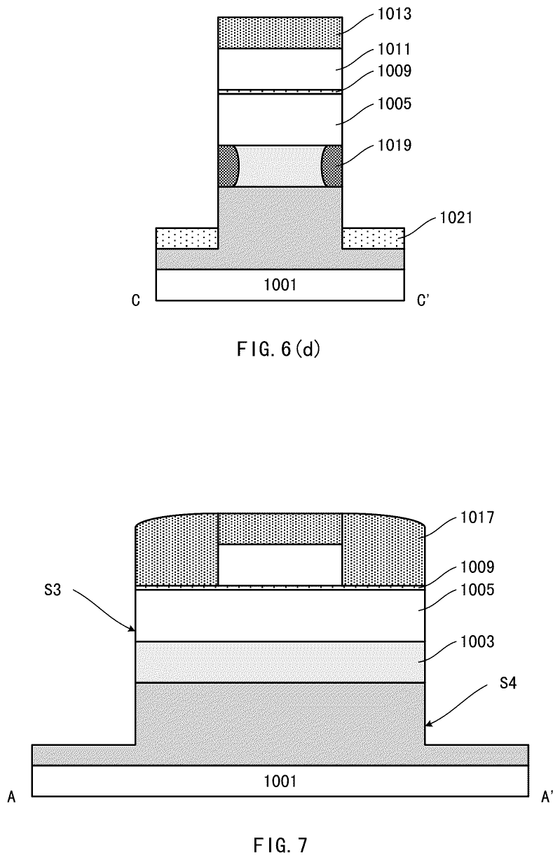

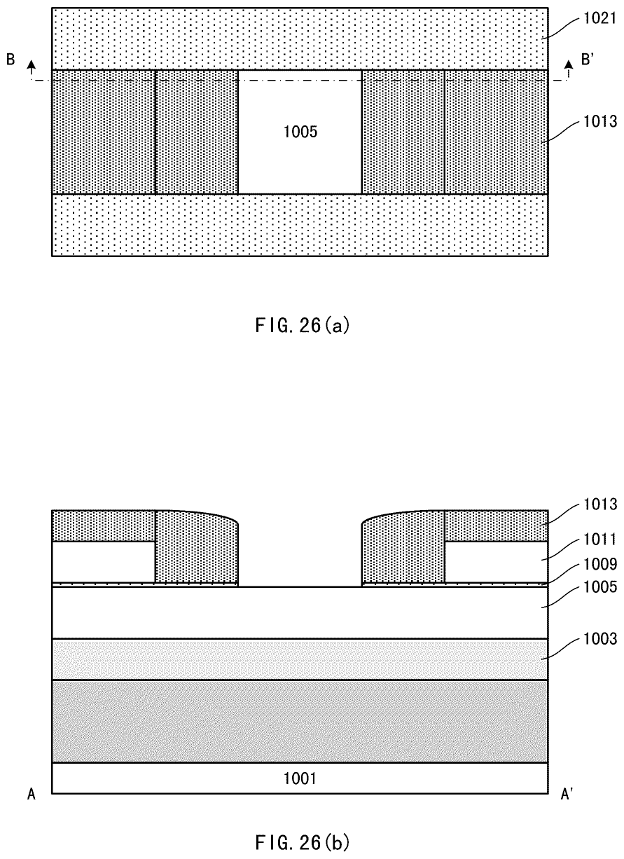

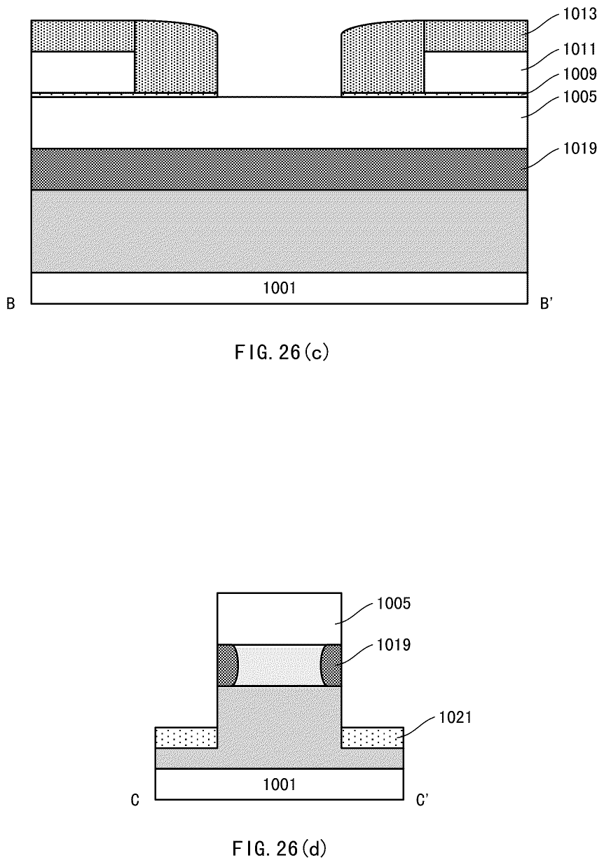

FIGS. 6(c) and 26(c) are cross-sectional views taken along line BB′;

FIGS. 5(c), 6(d), 25(c) and 26(d) are cross-sectional views taken along line CC′;

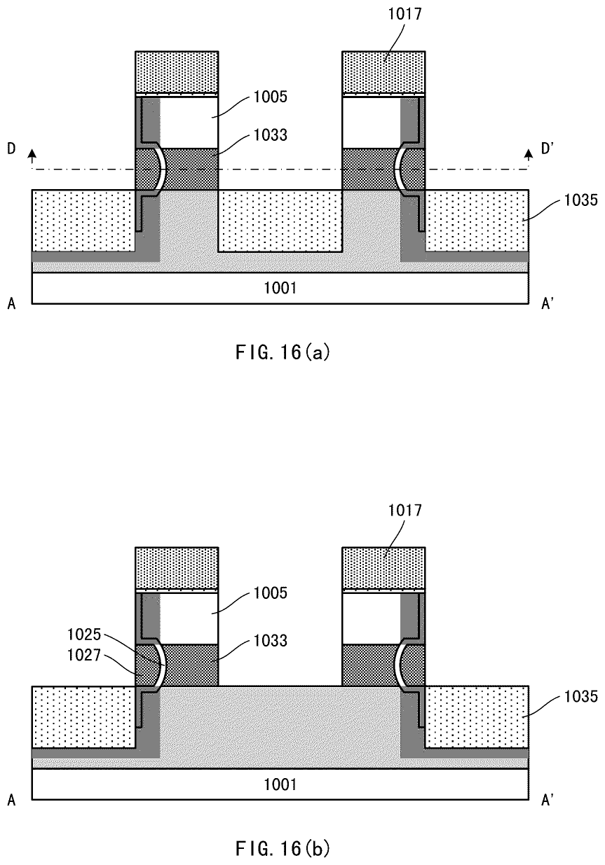

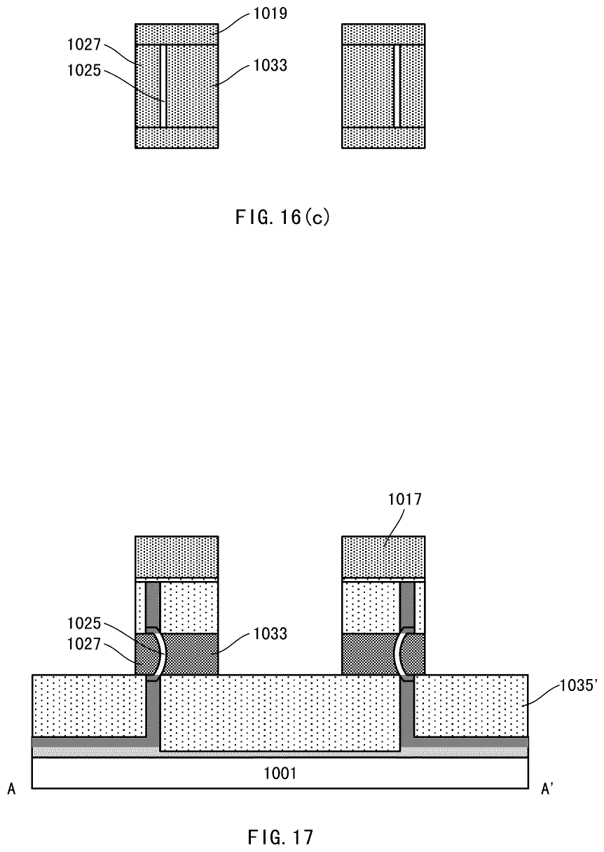

FIGS. 16(c), 19(d) and 21(d) are cross-sectional views taken along line DD′, where FIG. 16(a) shows a position of line DD′.

Throughout the accompanying drawings, the same or similar reference numbers indicate the same or similar components.

### DETAILED DESCRIPTION OF EMBODIMENTS

Hereinafter, embodiments of the present disclosure will be described with reference to accompanying drawings. However, it should be understood that these descriptions are illustrative and not intended to limit the scope of the present disclosure. Further, in the following, descriptions for known structures and technologies are omitted to avoid obscuring the concept of the present disclosure unnecessarily.

Various structures according to embodiments of the present disclosure are shown in the accompanying drawings. However, they are not drawn to scale, and some features may be enlarged while some features may be omitted for sake of clarity. Shapes, relative sizes and positions of regions and layers shown in the drawings are only illustrative, and deviations may occur due to manufacture tolerances or technique limitations in practice. In addition, those skilled in the art may devise regions/layers of other different shapes, sizes, and relative positions as desired in practice.

In the context of the present disclosure, when a layer/element is recited as being “on” a further layer/element, the layer/element may be disposed directly on the further layer/element, or otherwise there may be an intervening layer/element interposed therebetween. Further, if a layer/element is “on” a further layer/element in an orientation, then the layer/element may be “under” the further layer/element when the orientation is turned.

According to an embodiment of the present disclosure, a semiconductor device is provided. The semiconductor device has an active region part (e.g., referred to as a “semiconductor base”) provided laterally (e.g., in a direction substantially parallel to a substrate surface) on a substrate, and a pair of active region parts provided vertically (e.g., in a direction substantially perpendicular to the substrate surface) on the base. Such pair of vertical active region parts may include corresponding vertical channel portions (e.g., referred to as a “first vertical channel portion” and a “second vertical channel portion”) and corresponding source/drain portions (e.g., referred to as a “first source/drain portion” and a “second source/drain portion”) on the corresponding vertical channel portions. The first vertical channel portion and the second vertical channel portion may be spaced apart from each other in a first direction (for example, parallel to the substrate surface) and may be self-aligned with each other, for example, substantially coplanar with each other (as shown below; height positions of the first vertical channel portion and the second vertical channel portion in the vertical direction may be defined by the same material layer). The base may include a part (for example, may be referred to as a “lateral channel portion”) extending continuously between the first vertical channel portion and the second vertical channel portion. The gate stack may continuously extend on the surfaces of the first and second vertical channel portions as well as the lateral channel portion, so as to define a channel region in the channel portions. The channel region is a conductive channel between the first source/drain portion and the second source/drain portion.

Between the first vertical channel portion and the second vertical channel portion, the base may have a substantially flat upper surface. Alternatively, between the first vertical channel portion and the second vertical channel portion, the base may be recessed, so that the lateral channel portion may be in a curved shape, which may further increase the continuous gate length.

On the one hand, the semiconductor device has the characteristics of a vertical device due to the vertical channel portion, and on the other hand, the semiconductor device may have a continuous gate length, which may suppress the short channel effect.

Hereinafter, for the convenience of describing devices, sometimes a device part corresponding to the vertical channel portion is referred to as a “vertical composition device”, and a device part corresponding to the lateral channel portion is referred to as a “planar composition device”. Please note that the so-called (vertical/planar) composition device is a component of the semiconductor device according to embodiments of the present disclosure, rather than an independent device. The vertical composition device and the planar composition device are defined based on the shape of the channel portion (whether the channel portion is a vertical or lateral channel portion), but this does not mean that there are separate channels in the channel portion. The channel may extend continuously between the first source/drain portion and the second source/drain portion.

Each of the first vertical channel portion and the second vertical channel portion may include a curved nanosheet or nanowire, such as a nanosheet or nanowire with a C-shaped cross-section (perpendicular to the substrate surface and extending in the first direction). Therefore, such device may be referred to as the C-channel FET (CCFET). Each vertical channel portion may include one or more curved nanosheets or nanowires. In the case of a plurality of curved nanosheets or nanowires, such curved nanosheets or nanowires may be stacked sequentially in the first direction. As described below; (each) nanosheet or nanowire may be formed by epitaxial growth, so as to be integrated as a single piece with a substantially uniform thickness.

The curving directions of the first vertical channel portion and the second vertical channel portion may be opposite to each other. In other words, under the same curvature sign definition, a sign of a curvature of the first vertical channel portion may be opposite to a sign of a curvature of the second vertical channel portion, that is, using the same direction as the reference, one is convex and the other is concave. In addition, the first vertical channel portion may be substantially symmetrical with the second vertical channel portion. In other words, the curvatures of the first vertical channel portion and the second vertical channel portion at their respective positions (e.g., at the same height relative to the substrate) may have substantially the same absolute value.

The first source/drain portion and the second source/drain portion may be doped to a certain extent. For example, for p-type devices, the first source/drain portion and the second source/drain portion may be p-type doped; for n-type devices, the first source/drain portion and the second source/drain portion may be n-type doped. The vertical channel portion and/or the lateral channel portion may be doped to a certain extent to adjust the threshold voltage of the device.

The first source/drain portion and the second source/drain portion may be self-aligned with each other, for example, they may be provided in the same semiconductor layer. For example, the source/drain portion may be a doping region in the semiconductor layer. The source/drain portion may be a part of or the entire corresponding semiconductor layer. In the case where the source/drain portion is a part of the corresponding semiconductor layer, there may be a doping concentration interface between the source/drain portion and the rest of the corresponding semiconductor layer. As described below; the source/drain portion may be formed through diffusion doping. In this case, the doping concentration interface may be substantially in the vertical direction relative to the substrate.

In addition, the first source/drain portion may be self-aligned with the first vertical channel portion, and the second source/drain portion may be self-aligned with the second vertical channel portion. The first source/drain portion and the second source/drain portion may be self-aligned with the base below.

The channel portion may include a single crystal semiconductor material. Therefore, the source/drain portions or the semiconductor layers they are formed in may also include the single crystal semiconductor material. For example, the channel portion and the source/drain portion may all be formed through epitaxial growth.

The gate stack may (at least partially) surround the outer periphery of the vertical channel portion. Therefore, the vertical composition device may have a gate-all-around configuration. According to an embodiment of the present disclosure, the gate stack may be self-aligned with the vertical channel portion. For example, at least a part of the gate stack close to one side of the vertical channel portion may be substantially coplanar with the vertical channel portion.

Such semiconductor device may be manufactured as follows.

According to an embodiment, a stack of the first material layer, the second material layer, and the third material layer may be provided on the substrate. The first material layer may define the position of the base, the second material layer may define the position of the vertical channel portion, and the third material layer may define the position of the source/drain portion. The first material layer may be provided through the substrate, such as an upper part of the substrate. The second material layer and the third material layer may be sequentially formed on the first material layer through epitaxial growth, for example. Alternatively, the first material layer, the second material layer, and the third material layer may be sequentially formed on the substrate through epitaxial growth, for example. The third material layer may be doped in situ during epitaxial growth to form the source/drain portion in the third material layer.

The stack may be patterned as a ridge. The ridge may include first and second sidewalls extending in the first direction and opposite in the second direction intersecting with (e.g. perpendicular to) the first direction, as well as third and fourth sidewalls extending in the second direction and opposite in the first direction. The first sidewall to the fourth sidewall may form a closed shape (such as a rectangle) in the plan view. Alternatively, the ridge may include two parts separated by the third and fourth sidewalls in the first direction.

A shielding material may be formed on the first and second sidewalls of the ridge. In this way, subsequent processing may not affect the first and second sidewalls of the ridge, so as to form a gate stack on the side surface of the vertical channel portion in the first direction. Alternatively, in order to subsequently form the gate-all-around structure, a space for forming the gate stack may be defined at the first and second sidewalls of the ridge. For example, the sidewall of the second material layer may be laterally recessed relative to the sidewall of the first material layer and the sidewall of the third material layer at the first and second sidewalls of the ridge, so as to define a first recess portion. The first recess portion may have a curved surface recessed towards an inner side of the ridge. A first position retaining layer may be formed in the first recess portion.

Similarly, the sidewall of the second material layer may be laterally recessed relative to the sidewall of the first material layer and the sidewall of the third material layer at the third and fourth sidewalls of the ridge, so as to define a second recess portion for defining the space for the gate stack. The second recess portion may have a curved surface recessed towards the inner side of the ridge. The channel portion may be formed on the surface of the second recess portion. For example, a semiconductor layer may be formed by epitaxial growth on the exposed surface of the ridge. A part of the semiconductor layer on the (inward recessed) sidewall of the second material layer may be used as the vertical channel portion (therefore, the semiconductor layer may be referred to as the “channel layer”). For example, the channel layer at the third sidewall may define the first vertical channel portion, and the channel layer at the fourth sidewall may define the second vertical channel portion. A second position retaining layer may be formed in the second recess portion with the channel layer formed on the surface.

After defining the second recess portion and before forming the channel layer, the exposed surface of the ridge may be etched back by a certain amount, such as approximately the thickness of the channel layer to be formed. This helps to ensure that the subsequently formed gate stack has substantially equal gate lengths on the opposite sides of the vertical channel portion.

The ridge may be further patterned to form fifth and sixth sidewalls extending in the second direction and opposite in the first direction. The formation of the fifth and sixth sidewalls may expose the second material layer left in the ridge at the fifth and sixth sidewalls. For example, the fifth and sixth sidewalls may be located between the third and fourth sidewalls (in the case where the first to fourth sidewalls as described above form a closed pattern in the plan view), or the third and fourth sidewalls may be located between the fifth and sixth sidewalls (in the case where the ridge as described above includes two parts separated by the third and fourth sidewalls in the first direction). In the patterning, the first material layer may continuously extend in the first direction between the first vertical channel portion and the second vertical channel portion, so as to define the lateral channel portion.

At the fifth and sixth sidewalls, the second material layer may be removed to expose the channel layer, thereby defining the third recess portion. A third position retaining layer may be formed in the third recess portion.

The source/drain portion may be formed in the third material layer. For example, the source/drain portion may be formed by doping the third material layer (especially when the third material layer is not doped during formation). Such doping may be achieved through a solid-state dopant source layer.

At this point, the first position retaining layer, the second position retaining layer, and the third position retaining layer surround the vertical channel portion. The first position retaining layer, the second position retaining layer, and the third position retaining layer may be removed, and the gate stack may be formed. The gate stack may enter the position where the first position retaining layer, the second position retaining layer, and the third position retaining layer are originally occupied, thereby surrounding the vertical channel portion. In addition, the gate stack may extend on the lateral channel portion.

According to an embodiment of the present disclosure, the thickness of the nanosheet or nanowire of the vertical channel portion is mainly determined by epitaxial growth, rather than by etching or photolithography, and thus good channel size/thickness control may be achieved.

According to embodiments of the present disclosure, a vertical semiconductor device having a continuous gate length that well controls the short channel effect is provided.

The present disclosure may be presented in various forms, some examples of which will be described below. In the following description, a selection of various materials is involved. In the selection of materials, in addition to a function of the material (for example, a semiconductor material may be used to form an active region, a dielectric material may be used to form an electrical isolation), the etching selectivity is also considered. In the following description, the required etching selectivity may or may not be indicated. It should be clear to those skilled in the art that when etching a material layer is described below, if it is not described or shown that other layers are also etched, then the etching may be selective, and the material layer may have an etching selectivity relative to other layers exposed to the same etching recipe.

FIGS. 1 to 22(b) show schematic diagrams of some stages in a process of manufacturing a semiconductor device according to an embodiment of the present disclosure.

As shown in FIG. 1, a substrate 1001 (an upper part of the substrate 1001 may form the first material layer described above) is provided. The substrate 1001 may be in various forms, including but not limited to the bulk semiconductor material substrate such as the bulk Si substrate, the semiconductor on insulator (SOI) substrate, the compound semiconductor substrate such as SiGe substrate, etc. In the following description, for the convenience of explanation, the bulk Si substrate is taken as an example for description. Here, a silicon wafer is provided as the substrate 1001.

A well region may be formed in the substrate 1001. If the p-type device is to be formed, the well region may be an n-type well. If the n-type device is to be formed, the well region may be a p-type well. The well region may be formed, for example, by injecting a dopant with a corresponding conductivity type (p-type dopant such as B or In, or n-type dopant such as As or P) into the substrate 1001 and followed by thermal annealing. There are various ways to provide such well region in the art, which will not be further elaborated here.

A second material layer 1003 and a third material layer 1005 may be formed on the substrate 1001 by epitaxial growth, for example. The second material layer 1003 may be used to define the position of the vertical channel portion, with a thickness, for example, in a range of about 20 nm to 50 nm. The third material layer 1005 may be used to define the position of the source/drain portion, with a thickness, for example, in a range of about 20 nm to 200 nm.

The substrate 1001 and adjacent layers formed on the substrate 1001 may have etching selectivity relative to each other. For example, in the case where the substrate 1001 is the silicon wafer, the second material layer 1003 may include SiGe (e.g., an atomic percentage of Ge is in a range of about 10% to 30%), and the third material layer 1005 may include Si.

According to an embodiment, the spacer pattern transfer technique is used in the following patterning. A mandrel pattern may be formed to form a spacer. For example, as shown in FIG. 2, a layer 1011 used for the mandrel pattern may be formed on the third material layer 1005 by deposition. For example, the layer 1011 used for the mandrel pattern may include amorphous silicon or polycrystalline silicon, with a thickness in a range of about 50 nm to 150 nm. In addition, for better etching control, an etching stop layer 1009 may be formed by deposition. For example, the etching stop layer 1009 may include oxide (e.g. silicon oxide) with a thickness in a range of about 1 nm to 10 nm.

A hard mask layer 1013 may be formed on the layer 1011 used for the mandrel pattern by deposition. For example, the hard mask layer 1013 may include nitride (such as silicon nitride) with a thickness in a range of about 30 nm to 100 nm.

The layer 1011 used for the mandrel pattern may be patterned as the mandrel pattern.

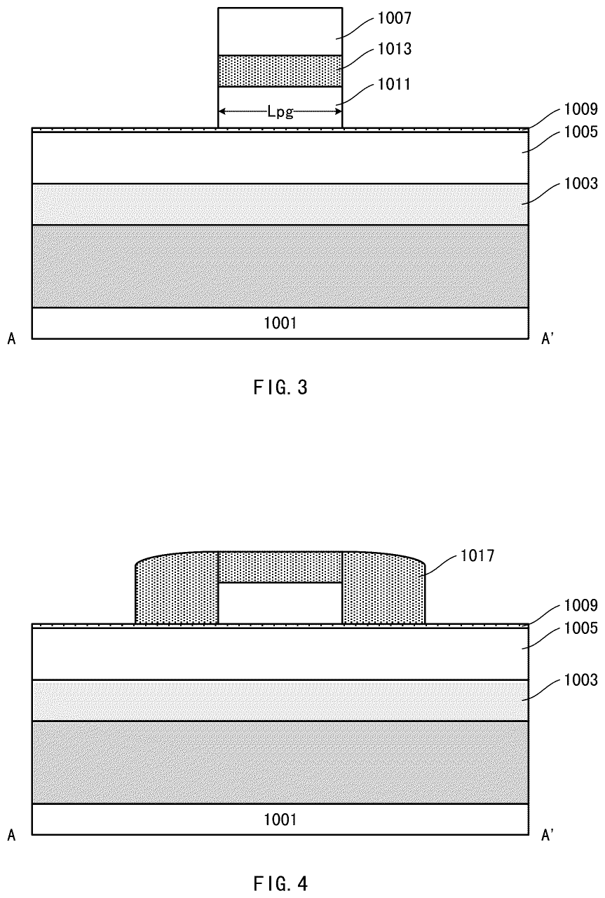

For example, as shown in FIG. 3, a photoresist 1007 may be formed on the hard mask layer 1013 and patterned by photolithography as a strip with a certain width in the first direction (for example, the horizontal direction within the paper surface in FIG. 3). The strip may extend in the second direction (for example, the direction perpendicular to the paper surface in FIG. 3) intersecting with (for example, perpendicular to) the first direction. The photoresist 1007 may be used as an etching mask to selectively etch the hard mask layer 1013 and the layer 1011 used for the mandrel pattern sequentially, for example, through reactive ion etching (RIE). The pattern of the photoresist may be transferred to the hard mask layer 1013 and the layer 1011 used for the mandrel pattern. The etching may stop at the etching stop layer 1009. Afterwards, the photoresist 1007 may be removed.

As shown in FIG. 3, the layer 1011 used for the mandrel pattern is patterned as a mandrel pattern with a certain width Lpg in the first direction. The width Lpg may then define the gate length (or the length of the lateral channel portion) of the planar composition device, or partially contribute to the gate length of the semiconductor device according to embodiments of the present disclosure.

As shown in FIG. 4, a spacer 1017 may be formed on opposite sides of the mandrel pattern 1011 in the first direction. For example, a layer of nitride with a thickness in a range of about 10 nm to 100 nm may be deposited in a substantially conformal manner, and then anisotropic etching such as RIE (which may stop at the etching stop layer 1009) may be performed on the deposited nitride layer in the vertical direction, so as to remove a lateral extension part of the nitride layer and leave a vertical extension part of the nitride layer, thereby obtaining the spacer 1017. The spacer 1017 may then be used to define the position of the vertical active region part.

The mandrel pattern formed as described above and the spacer 1017 formed on the sidewall of the mandrel pattern extend in the second direction. The range of the mandrel pattern and the spacer 1017 in the second direction may be defined, so as to define the range of the active region of the semiconductor device to be manufactured in the second direction.

As shown in FIGS. 5(a) to 5(c), a photoresist 1015 may be formed on the structure shown in FIG. 4 and patterned by photolithography to occupy a certain range in the second direction, such as a strip extending in the first direction. The photoresist 1015 may be used as an etching mask to selectively etch the lower layers in sequence by, such as RIE. The etching may be performed in the substrate 1001, especially in the well region, so as to form a trench in the substrate 1001. Isolation, such as shallow trench isolation (STI), may then be formed in the formed trench. Afterwards, the photoresist 1015 may be removed.

As shown in FIG. 5(c), the first sidewall S1 and the second sidewall S2 opposite to each other in the second direction are defined. The first sidewall S1 and the second sidewall S2 may extend in the first direction. In addition, the second material layer 1003 may expose at the first sidewall S1 and the second sidewall S2.

According to an embodiment of the present disclosure, in order to form the gate stack surrounding the vertical channel portion, a space for the gate stack may be left at both ends of the second material layer in the second direction.

For this, as shown in FIGS. 6(a) to 6(d), selective etching may be performed on the second material layer 1003 to recess the second material layer 1003 at the first sidewall S1 and the second sidewall S2. To better control the etching amount, atomic layer etching (ALE) may be used. For example, the etching amount may be in a range of about 5 nm to 20 nm. Depending on the etching characteristics, such as the etching selectivity of the second material layer 1003 relative to the substrate 1001 and the third material layer 1005, the sidewall of the etched second material layer 1003 may be in a different shape. FIG. 6(d) shows that the sidewall of the etched second material layer 1003 is in a curved shape, such as a C-shape recessed inward. However, the present disclosure is not limited to this. For example, when the etching selectivity is great, the sidewall of the etched second material layer 1003 may be substantially vertical. Here, the etching may be isotropic, especially when a large etching amount is desired. Such formed recess may be filled with a dielectric material to define the space for the gate stack. Such filling may be performed by deposition followed by etching back. For example, a dielectric material such as SiC that is sufficient to fill the recess may be deposited on the substrate, and then the deposited dielectric material may be etched back by, such as RIE. In this way, the dielectric material outside the region defined by the hard mask layer 1013 and the spacer 1017 may be removed, and the dielectric material is left in the above-described recess to form a first position retaining layer 1019.

According to an embodiment of the present disclosure, a protective layer 1021 may be formed on the substrate 1001. For example, an oxide layer may be formed on the substrate 1001 by deposition, and the deposited oxide layer may be planarized by, for example, chemical mechanical polishing (CMP) (CMP may stop at the hard mask layer 1013) and further etched back to form the protective layer 1021. Here, the protective layer 1021 may be located in the trench of the substrate 1001. A top surface of the protective layer 1021 is lower than the top surface of the substrate 1001. In addition, in the etching back process, the exposed part of the etching stop layer 1009 (also an oxide in this example) may also be etched. According to other embodiments, the operation of forming the protective layer 1021 may be performed before the operation (including recessing and filling) of forming the first position retaining layer 1019.

The protective layer 1021 may protect the surface of the substrate 1001. For example, in this example, the range of the active region in the second direction is defined. Then, the range of the active region in the first direction is defined. The protective layer 1021 may be used to avoid affecting the surface (see FIG. 5(c)) of the substrate currently exposed in the trench when defining the range in the first direction. In addition, in the case where different types of well regions are formed in the substrate 1001, the protective layer 1021 may be used to protect the pn junction between different types of well regions from being etched (such as the etching back when forming the first position retaining layer 1019).

As shown in FIG. 7, the third material layer 1005, the second material layer 1003, and the upper part (the first material layer) of the substrate 1001 may be patterned as a ridge using the hard mask layer 1013 and the spacer 1017 (in fact, the range of the ridge in the second direction is defined by the above processing). For example, selectively etching such as RIE may be performed on the layers sequentially using the hard mask layer 1013 and the spacer 1017 as etching masks, so as to transfer the pattern to the lower layers. Therefore, the upper part of the substrate 1001, the second material layer 1003, and the third material layer 1005 may form the ridge. As described above, due to the presence of the protective layer 1021, the etching may not affect the part of the substrate 1001 on both sides of the ridge in the second direction. Similarly, the third sidewall S3 and the fourth sidewall S4 opposite to each other in the first direction are defined. The third sidewall S3 and the fourth sidewall S4 may extend in the second direction. More specifically, the ridge is defined by the first sidewall S1, the second sidewall S2, the third sidewall S3, and the fourth sidewall S4.

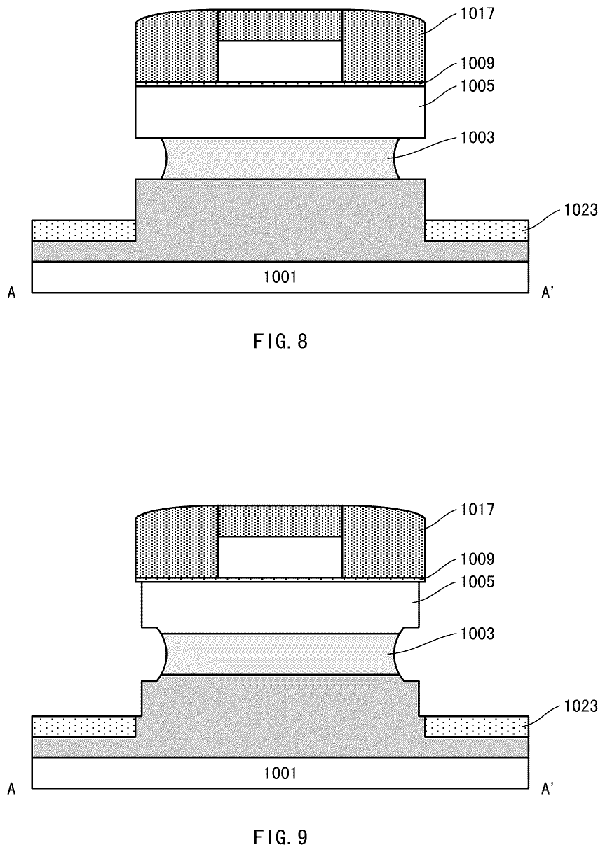

The etching may be entered in the well region of the substrate 1001. The etching degree entering the substrate 1001 may be substantially the same or similar to the etching degree entering the substrate 1001 described above in combination with FIGS. 5(a) to 5(c). Similarly, a trench may be formed in the substrate 1001, and a protective layer (see 1023 in FIG. 8) may be formed in the trench. The protective layer 1023, along with the previous protective layer 1021, surrounds the periphery of the ridge. In this way, similar processing conditions may be achieved around the ridge, that is, the trenches are formed in the substrate 1001, and the protective layers 1021 and 1023 are formed in the trenches.

Similarly, in order to form the gate stack surrounding the vertical channel portion, the space for the gate stack may be left at both ends of the second material layer in the first direction. For example, as shown in FIG. 8, selective etching may be performed on the second material layer 1003 to recess the second material layer 1003 at the third sidewall S3 and the fourth sidewall S4. ALE may be used to better control the etching amount. For example, the etching amount may be in a range of about 10 nm to 40 nm. As described above, the sidewall of the etched second material layer 1003 may be in a curved shape, such as a C-shape recessed inward. Here, the etching may be isotropic, especially when a large etching amount is desired. Usually, the curved sidewall of the second material layer 1003 has a larger curvature at the upper and lower ends, as well as a smaller curvature at the waist or middle.

A channel layer may be formed at the third sidewall S3 and the fourth sidewall S4 to subsequently define the vertical channel portion. In order to ensure that the gate lengths (e.g., in the direction perpendicular to the substrate surface) of the gate stacks subsequent formed on opposite sides of the (e.g., curved) vertical channel portion in the first direction may be substantially equal to each other, as shown in FIG. 9, the ridge (specifically, the exposed surfaces of the first material layer, the second material layer, and the third material layer) may be etched back, so that the outer sidewall of the ridge is laterally recessed relative to the outer sidewall of the spacer 1017. ALE may be used to control the etching depth. The etching depth may be substantially equal to the thickness of the channel layer to be grown subsequently, for example, in a range of about 5 nm to 15 nm.

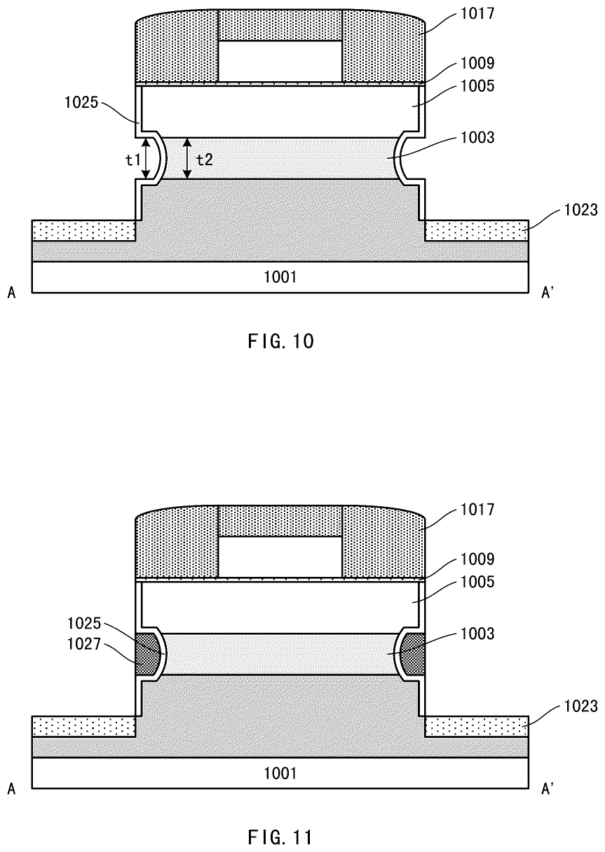

Next, as shown in FIG. 10, a channel layer 1025 may be formed on the third sidewall S3 and the fourth sidewall S4 of the ridge through selective epitaxial growth, for example. Due to selective epitaxial growth, the channel layer 1025 may not be formed on the surface of the first position retaining layer 1019. The channel layer 1025 may then define the vertical channel portion, with a thickness in a range of about 3 nm to 15 nm. According to embodiments of the present disclosure, the thickness of the channel layer 1025 (subsequently used as the vertical channel portion) may be determined by the epitaxial growth process, so that the thickness of the vertical channel portion may be better controlled. The channel layer 1025 may be doped in situ during epitaxial growth to regulate the threshold voltage of the device.

As shown in FIG. 10, a sidewall of a part of the channel layer 1025 on the sidewall of the first material layer and a sidewall of a part of the channel layer 1025 on the sidewall of the third material layer are substantially flush with the sidewall of the spacer 1017, which may be achieved by controlling the etching amount to be substantially identical to the thickness of epitaxial growth. However, the present disclosure is not limited to this. For example, the sidewalls of the parts of the channel layer 1025 on the sidewall of the first material layer and the sidewall of the third material layer may be recessed relative to the sidewall of the spacer 1017, or may even protrude relative to the sidewall of the spacer 1017.

Here, the upper and lower ends of the recess portion may be etched upwards and downwards respectively by the above-described etching back, so that after growing the channel layer 1025, the height t1 of the recess portion may be substantially the same as the thickness t2 of the second material layer 1003. In this way, the gate stacks formed on the opposite sides of the channel layer 1025 in the first direction may have substantially equal gate lengths. However, the present disclosure is not limited to this. According to embodiments of the present disclosure, the gate length on the outer side of the channel layer 1025 may also be adjusted by adjusting the etching back amount to change the ratio of gate lengths on both sides, so as to reduce the impact of different morphologies at opposite sides of the (e.g. curved) vertical channel portion on the performance of the device.

The material of the channel layer 1025 may be selected appropriately according to the performance requirements of the device in the design. For example, the channel layer 1025 may include various semiconductor materials, such as Si, Ge, SiGe, InP, GaAs, InGaAs, etc. In this example, the channel layer 1025 may include the same material as the first and third material layers, such as Si. In addition, the channel layer 1025 may also include a multi-layer structure.

In the example of FIG. 10, the channel layers 1025 at the third sidewall S3 and the fourth sidewall S4 of the ridge may have substantially the same features (such as material, size, doping characteristics, etc.), and may be substantially symmetrically provided on opposite sides of the second material layer in the first direction.

Due to the recess of the second material layer 1003, a gap is formed on the outer side of the part of the channel layer 1025 corresponding to the second material layer 1003. The gate stack may then be formed in such gap. To prevent unnecessary materials left in the gap by subsequent treatments or affecting the channel layer 1025, as shown in FIG. 11, a second position retaining layer 1027 may be formed in such gap. Similarly, the second position retaining layer 1027 may be formed by deposition followed by etching back, and may include the dielectric material such as SiC. In this example, the first position retaining layer 1019 and the second position retaining layer 1027 include the same material, so that they may be subsequently removed together with the same etching recipe. However, the present disclosure is not limited to this, for example, the first position retaining layer 1019 and the second position retaining layer 1027 may include different materials.

Next, source/drain doping may be performed.

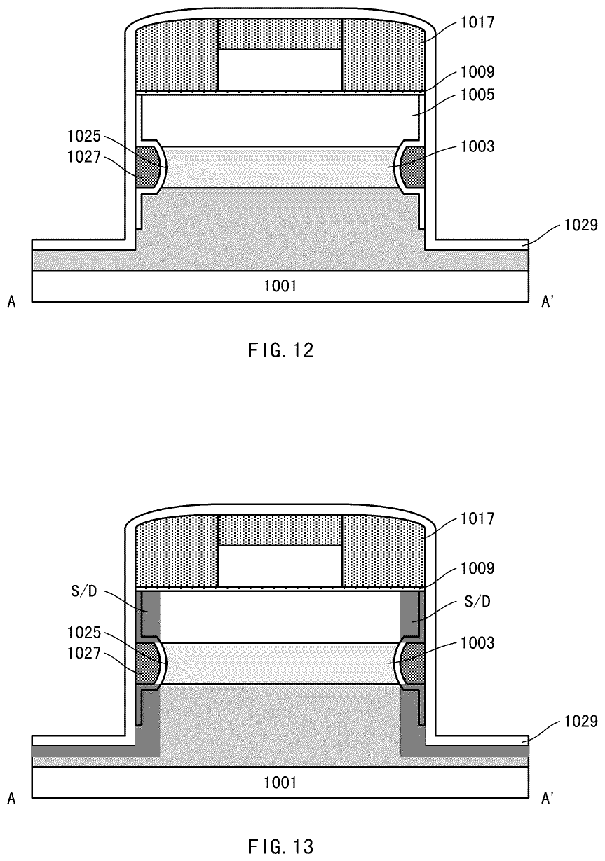

As shown in FIG. 12, a solid-state dopant source layer 1029 may be formed on the structure shown in FIG. 11, for example, by deposition. The solid-state dopant source layer 1029 may be formed in a substantially conformal manner. For example, the solid-state dopant source layer 1029 may be an oxide containing a dopant, with a thickness in a range of about 1 nm to 5 nm. The dopant contained in the solid-state dopant source layer 1029 may be used to dope the source/drain portion, so that the source/drain portion may have a desired conductivity type. For example, for p-type devices, the solid-state dopant source layer 1029 may contain a p-type dopant such as B or In. For n-type devices, the solid-state dopant source layer 1029 may contain an n-type dopant such as P or As. The concentration of the dopant in the solid-state dopant source layer 1029 may be in a range of about 0.1% to 5%.

The dopant in the solid-state dopant source layer 1029 may be driven into the third material layer (and the channel layer on the sidewall of the third material layer) through annealing to form the source/drain portion S/D, as shown in FIG. 13. Afterwards, the solid-state dopant source layer 1029 may be removed.

The dopant in the solid-state dopant source layer 1029 may also be driven into the first material layer (and the channel layer on the sidewall of the first material layer), so as to form a doping region in the first material layer with a doping condition similar to that of S/D. The doping region may also serve as a source/drain and may be led out, so as to obtain a multi-electrode transistor. In this example, as the first and third material layers may have the same material, and the solid-state dopant source layer 1029 may be formed on the surfaces of the first and third material layers in a substantially conformal manner, the driving degree of the dopant from the solid-state dopant source layer 1029 into the first material layer may be substantially the same as the driving degree of the dopant from the solid-state dopant source layer 1029 into the third material layer. Therefore, the (doping concentration) interfaces (between inner parts of the first material layer and the third material layer and) the doping regions formed in the first material layer and the third material layer may be substantially parallel to the surfaces of the first material layer and the third material layer, that is, the interfaces may be in the vertical direction and aligned with each other.

In this example, before forming the solid-state dopant source layer 1029, selectively etching such as RIE may be performed on the protective layers 1021 and 1023 to expose the surface of the substrate 1001. Therefore, a doping region (with a doping concentration greater than that of the well region) may also be formed on the lateral surface of the substrate 1001. However, the present disclosure is not limited to this. For example, the solid-state dopant source layer 1029 may also be formed while retaining the protective layers 1021 and 1023.

In this example, the source/drain portion is formed through diffusion doping. However, the present disclosure is not limited to this. For example, the third material layer may be doped in situ during epitaxy. The first material layer may be an epitaxial layer on the substrate 1001, and may also be doped in situ during epitaxy.

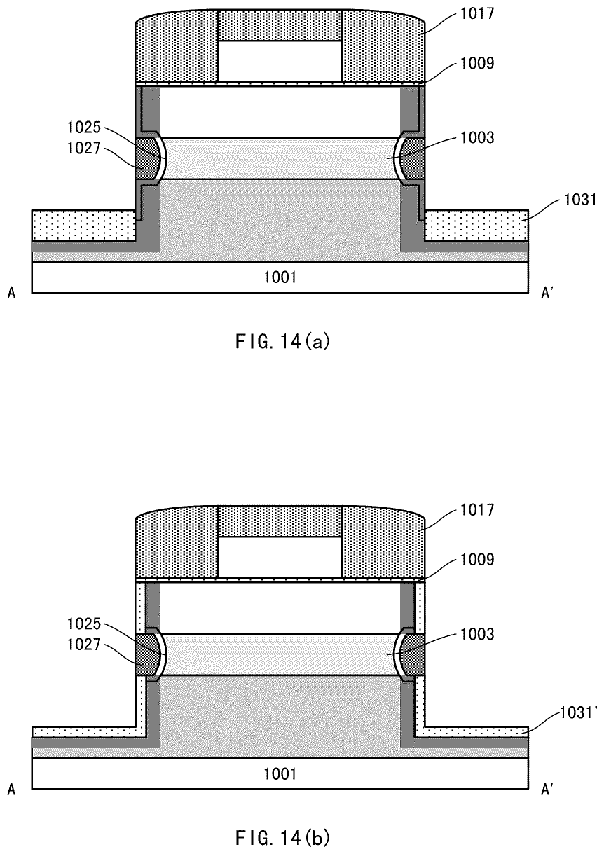

An isolation layer 1031 may be formed in the trenches around the ridge, as shown in FIG. 14(a). The method of forming the isolation layer may be similar to the method of forming the protective layers 1021 and 1023 as described above, which will not be repeated here.

To reduce the capacitance between the gate and the source/drain, the overlap between the gate and the source/drain may be further reduced. For example, as shown in FIG. 14(b), after removing the solid-state dopant source layer 1029, selective etching may be used to further recess the source/drain portion S/D, so as to reduce the overlap between the source/drain portion S/D and the first position retaining layer 1019 as well as the second position retaining layer 1027 (subsequently defining the position of the gate stack). In this example, when the source/drain portion S/D is further recessed, the parts of the channel layer 1025 on the sidewalls of the first and third material layers are removed, and the first and third material layers may be further recessed. The gap formed due to the recess of the source/drain portion S/D below the hard mask layer 1013 and the spacer 1017 may be filled with a dielectric 1031′ such as nitrogen oxide or oxide. The filling may be achieved by deposition (and planarization) followed by etching back. During etching back, the dielectric 1031′ with a certain thickness is left on the surface of the substrate 1001 to form an isolation portion.

Hereinafter, for convenience, the case shown in FIG. 14(a) is still used as an example for description.

Next, the spacer 1017 may be used to define the active region.

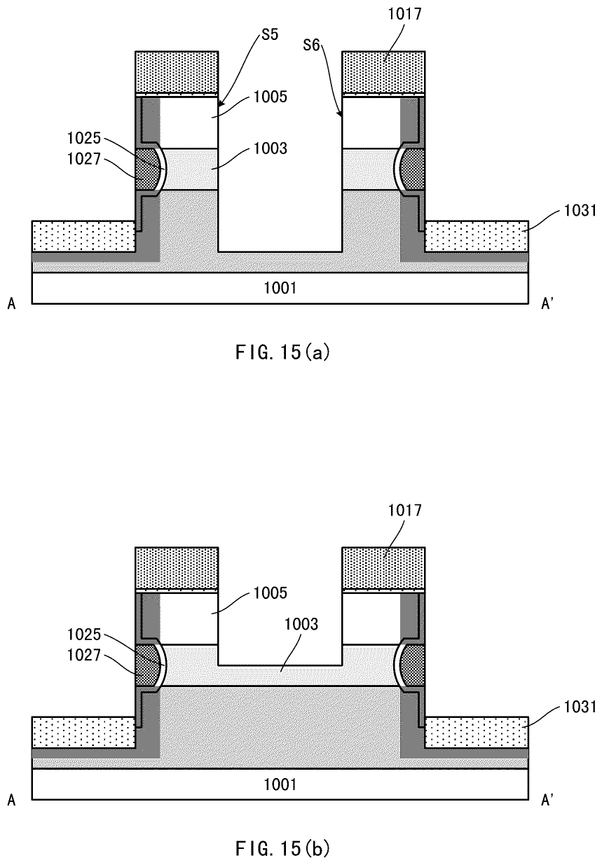

As shown in FIG. 15(a), the hard mask layer 1013 may be removed by selective etching such as RIE or planarization processing such as CMP, so as to expose the mandrel pattern 1011. In the process of removing the hard mask layer 1013, the height of the spacer 1017, which is also nitride in this example, may be decreased. Then, the mandrel pattern 1011 may be removed by selective etching, such as wet etching using TMAH solution or dry etching using RIE. In this way, a pair of spacers 1017 (with a decrease in height and possible changes in the morphology of the top) extending opposite to each other is left on the ridge.

Selectively etching such as RIE may be performed on the etching stop layer 1009, the third material layer 1005, the second material layer 1003, and the upper part of the substrate 1001 sequentially using the spacer 1017 as the etching mask. The etching may be performed into the well region of the substrate 1001. In this way, within the space surrounded by the isolation layer 1031, a pair of stacks corresponding to the spacers 1017 is formed by the third material layer 1005, the second material layer 1003, and the upper part of the substrate 1001. The formation of such pair of stacks is not limited to the spacer pattern transfer technology, but may also be achieved through photolithography using the photoresist.

In addition, the exposed part of the first material layer may define the lateral active region part. According to another embodiment, as shown in FIG. 15(b), the etching may stop in the second material layer 1003.

Similarly, the fifth sidewall S5 and the sixth sidewall S6 opposite to each other in the first direction may be defined. The fifth sidewall S5 and the sixth sidewall S6 may extend in the second direction. The second material layer may be exposed due to the fifth sidewall S5 and the sixth sidewall S6.

For the purpose of epitaxial growth, the second material layer 1003 used to define the position of the vertical channel portion includes the semiconductor material. For the convenience of subsequent gate replacement process, the second material layer 1003 may be replaced with a dielectric material to form a third position retaining layer.

For example, as shown in FIGS. 16(a) and 16(b) (corresponding to FIGS. 15(a) and 15(b) respectively), the second material layer 1003 (SiGe in this example) may be removed by selective etching relative to the channel layer 1025, the substrate 1001, and the third material layer 1005 (all Si in this example). Then, a third position retaining layer 1033 may be formed in the gap left due to the removal of the second material layer 1003 below the spacer 1017. Similarly, the third position retaining layer 1033 may be formed by deposition followed by etching back. In this example, the third position retaining layer 1033 may include the same material as the first position retaining layer 1019 and the second position retaining layer 1027, so that the first position retaining layer 1019, the second position retaining layer 1027 and the third position retaining layer 1033 may be removed with the same etching recipe in the following gate replacement process.

In the case shown in FIG. 16(b), the substantially flat top surface of the first material layer may be exposed, which may define the lateral active region part.

As shown in FIG. 16(c), the first position retaining layer 1019, the second position retaining layer 1027, and the third position retaining layer 1033 (which define the position of the gate stack together) surround a part of the channel layer 1025. Such part of the channel layer 1025 may be used as the vertical channel portion. It may be seen that the vertical channel portion may be a curved nanosheet in a C-shape (when the nanosheet is narrow, for example, when the size of the nanosheet in a direction perpendicular to the paper surface in FIG. 16(b) is small, the nanosheet may become the nanowire). Due to the high etching selectivity of the second material layer 1003 (SiGe) relative to the channel layer 1025 (Si) during etching, the thickness of the vertical channel portion (in the case of nanowires, which is the thickness or diameter of the vertical channel portion) is substantially determined by the selective growth process of the channel layer 1025. This has significant advantages over using only etching or photolithography methods to determine the thickness, as epitaxial growth processes have much better process control compared to etching or photolithography.

To form a self-aligned gate stack, the height of the isolation layer 1031 may be increased. For example, an isolation layer 1035 may be formed by deposition (and planarization) followed by etching back. For example, the isolation layer 1035 may include oxide and thus may be integrated with the previous isolation layer 1031. The top surface of the isolation layer 1035 may be close to, for example, not lower than (preferably slightly higher than) the top surface of the first material layer (i.e., the top surface of the substrate 1001) or the bottom surface of the second material layer (i.e., the bottom surfaces of the first position retaining layer 1019, the second position retaining layer 1027, and the third position retaining layer 1033), and not higher than the top surface of the second material layer (i.e., the top surfaces of the first position retaining layer 1019, the second position retaining layer 1027, and the third position retaining layer 1033) or the bottom surface of the third material layer.

According to another embodiment of the present disclosure, in order to reduce the capacitance, the overlap between the gate and the first and third material layers (where source/drain portions are formed) may be further reduced. For example, as shown in FIG. 17, after forming the third position retaining layer 1033 as described above, the exposed surfaces of the first and third material layers may be further recessed by selective etching. As a result, the overlap between the first and third material layers and the third position retaining layer 1033 (subsequently defining the position of the gate stack) is reduced. Afterwards, an isolation layer 1035′ may be similarly formed. During the formation of the isolation layer 1035′, the gap formed due to the recess of the third material layer below the spacer 1017 may also be filled with the dielectric material of the isolation layer 1035′.

FIG. 17 shows the structure obtained by performing the process of reducing overlap described in reference to FIG. 17 in addition to the process of reducing overlap described in reference to FIG. 14(b). Therefore, the periphery of the source/drain portion S/D is surrounded by the dielectric material. However, the present disclosure is not limited to this. For example, either or both the process of reducing overlap described in reference to FIG. 14(b) and the process of reducing overlap described in reference to FIG. 17 may be performed.

In the following, the case shown in FIGS. 16(a) and 16(b) is still used as an example for description.

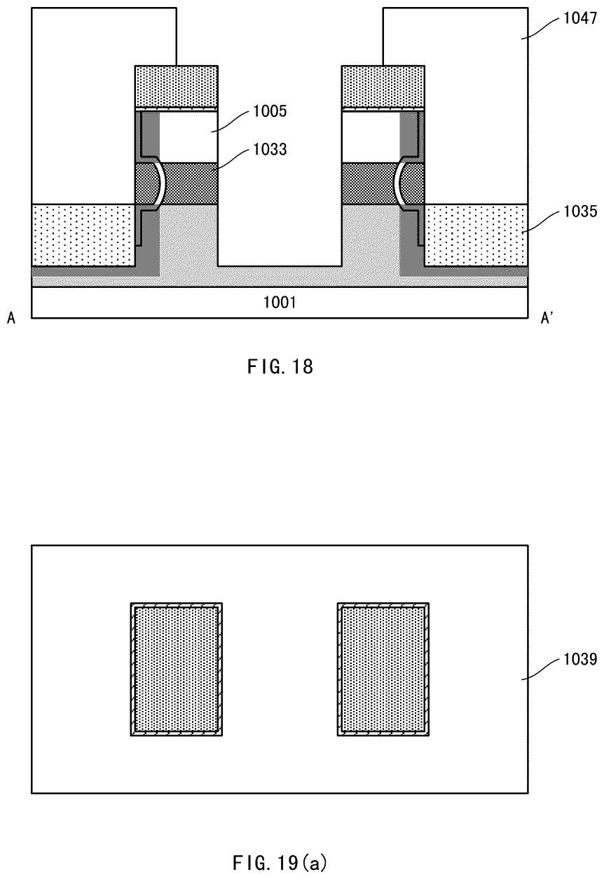

For the case shown in FIG. 16(a), a part of the first material layer between the vertical channel portions is covered by the isolation layer 1035. As shown in FIG. 18, a photoresist 1047 may be formed on the isolation layer 1035 and patterned to expose at least a part of the isolation layer 1035 that extends continuously between the opposite vertical channel portions. The exposed part of the isolation layer 1035 may be removed by selective etching, such as RIE, so that a part of the first material layer that extends continuously between the opposite vertical channel portions may be exposed. Such part of the first material layer may be used to define the lateral channel portion. Afterwards, the photoresist 1047 may be removed.

For the lateral channel portion (such as the exposed surface of the substrate 1001 shown in FIG. 16(b) or FIG. 18), doping may be optionally performed by, for example, ion implantation, so as to adjust the threshold voltage of the device.

Next, the gate replacement process may be performed to form the gate stack.

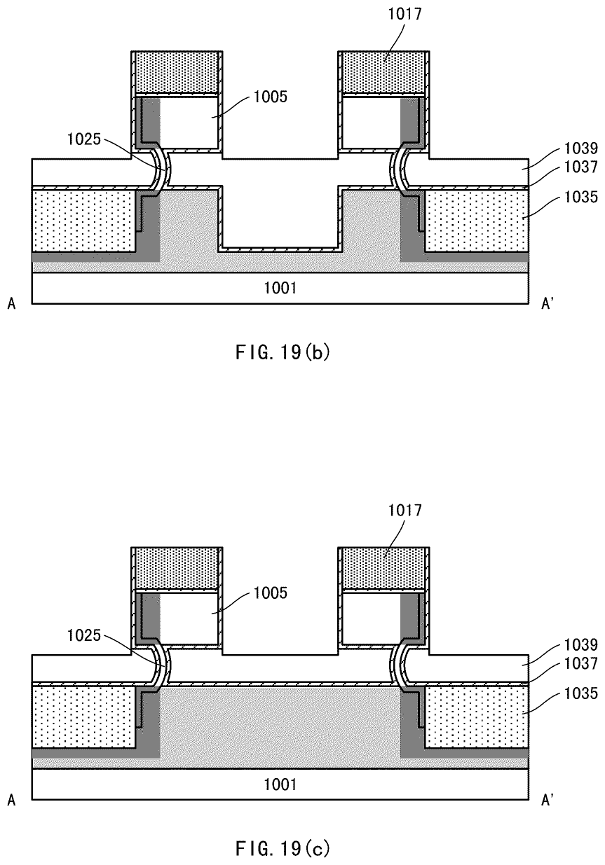

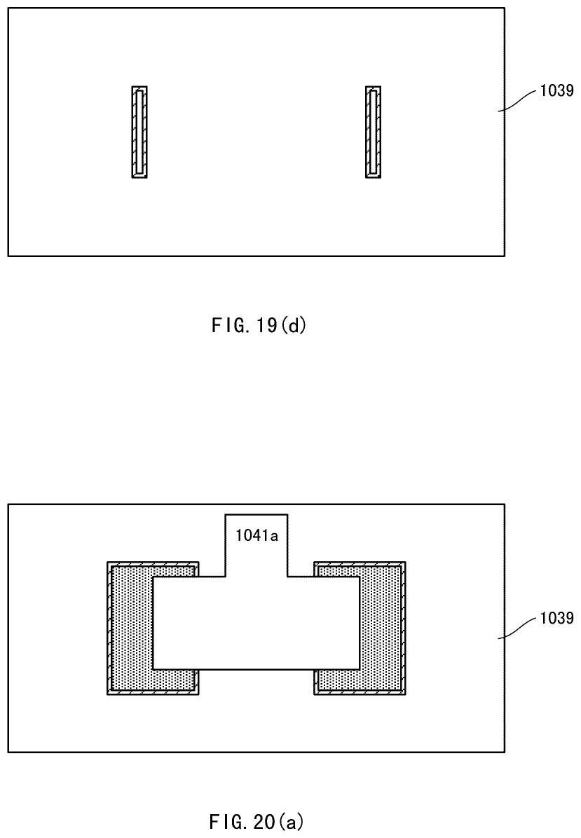

As shown in FIGS. 19(a) to 19(d), the first position retaining layer 1019, the second position retaining layer 1027, and the third position retaining layer 1033 may be removed by selective etching, and a gate stack may be formed on the isolation layer 1035. For example, a gate dielectric layer 1037 may be formed in a substantially conformal manner by deposition, and a gate conductor layer 1039 may be formed on the gate dielectric layer 1037. The gate conductor layer 1039 may be planarized by CMP, and CMP may stop at the spacer 1017. Then, the gate conductor layer 1039 may be etched back, so that a top surface of the gate conductor layer 1039 is lower than the top surfaces of the original first position retaining layer 1019, the second position retaining layer 1027, and the third position retaining layer 1033 (or, the top surface of the second material layer or the bottom surface of the third material layer) to reduce the capacitance between the source/drain portion and the gate stack. In this way, the end of the formed gate stack is embedded into the space where the first position retaining layer 1019, the second position retaining layer 1027, and the third position retaining layer 1033 are previously located, surrounding the vertical channel portion.

For example, the gate dielectric layer 1037 may include a high k gate dielectric such as HfO₂, with a thickness in a range of about 1 nm to 5 nm. Before forming the high k gate dielectric, an interface layer may be formed, such as oxide formed through the oxidation process or deposition such as atomic layer deposition (ALD), with a thickness in a range of about 0.3 nm to 1.5 nm. The gate conductor layer 1039 may include work function regulating metals such as TiN, TaN, TiAlC, as well as a gate conductive metal such as W.

It may be seen that on the one hand, the gate stack extends on the surface of the vertical channel portion, so as to define the vertical channel, and on the other hand, the gate stack extends on the lateral channel portion between two vertical channel portions, so as to define the lateral channel. In the case shown in FIG. 19(b), the lateral channel may be in a curved shape caused by the recess of the first material layer (the length of the lateral channel may be further increased). In the case shown in FIG. 19(b), the lateral channel may be in a substantially flat shape.

The gate conductor layer 1039 may be patterned to define a landing pad of the gate contact portion.

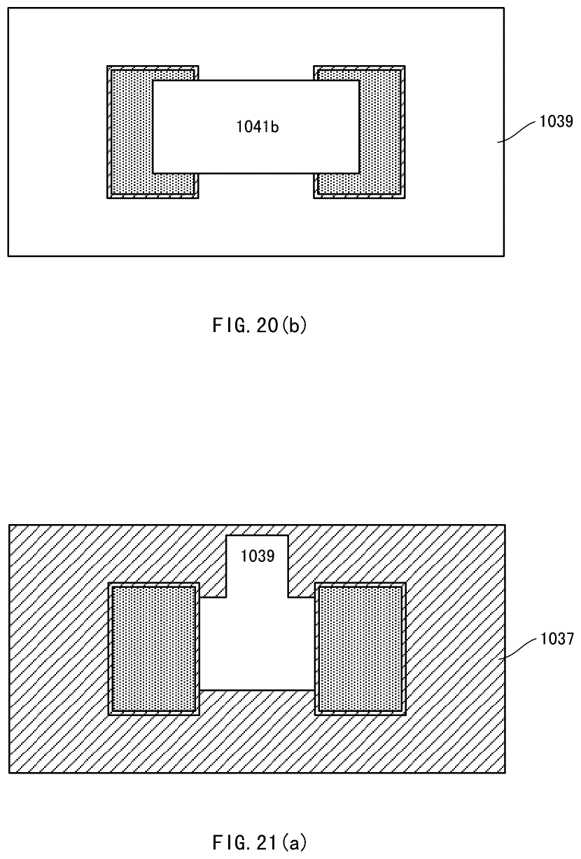

As shown in FIGS. 20(a) and 20(b), a photoresist 1041a or 1041b may be formed and patterned as a region for shielding the landing pad of the gate contact portion to be formed and exposing other regions. Here, the difference between the photoresists 1041a and 1041b is only that the shapes and/or sizes of the landing pads to be formed may be different. In the following, for convenience only, the case shown in FIG. 20(a) will be used as an example for description.

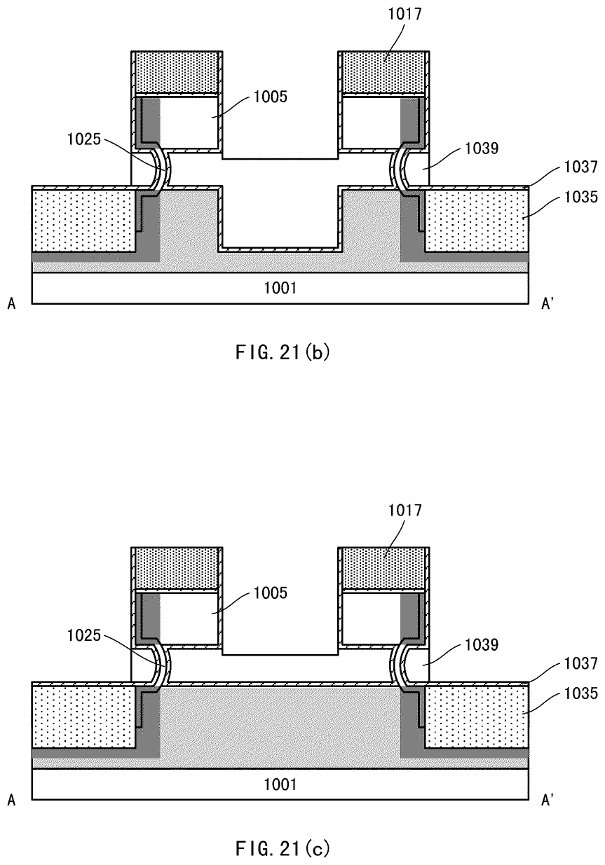

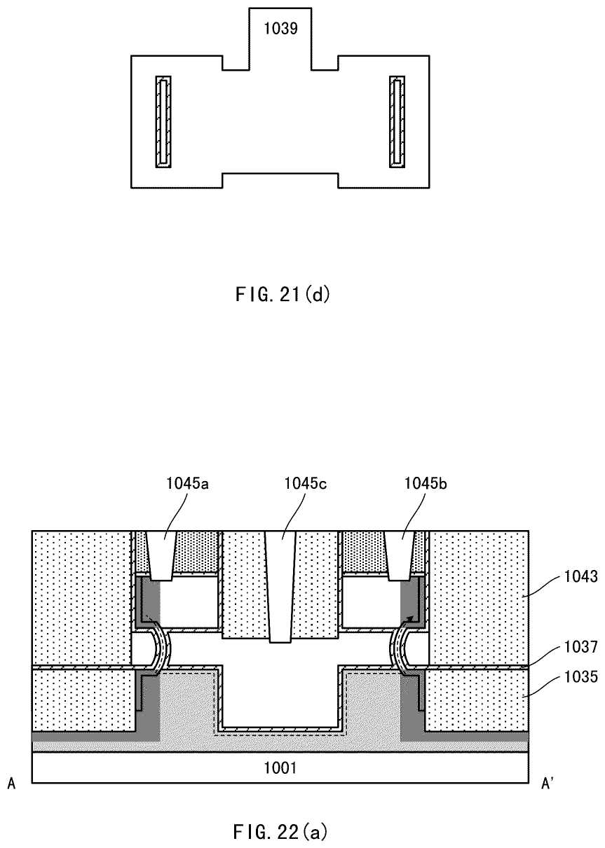

Next, as shown in FIGS. 21(a) to 21(d), selective etching such as RIE may be performed on the gate conductor layer 1039 using the photoresist 1041a (and the spacer 1017) as a mask. RIE may stop at the gate dielectric layer 1037. Afterwards, the photoresist 1041a may be removed.

Therefore, the gate conductor layer 1039 is substantially left and self-aligned below the spacer 1017, except for leaving a part between the two spacers 1017 to be used as the landing pad. FIG. 21(d) clearly illustrates that the gate stack surrounds the outer peripheries of the vertical channel portions.

At this point, the fabrication of the base structure of the device is completed. Subsequently, various contact portions, interconnection structures, etc. may be fabricated.

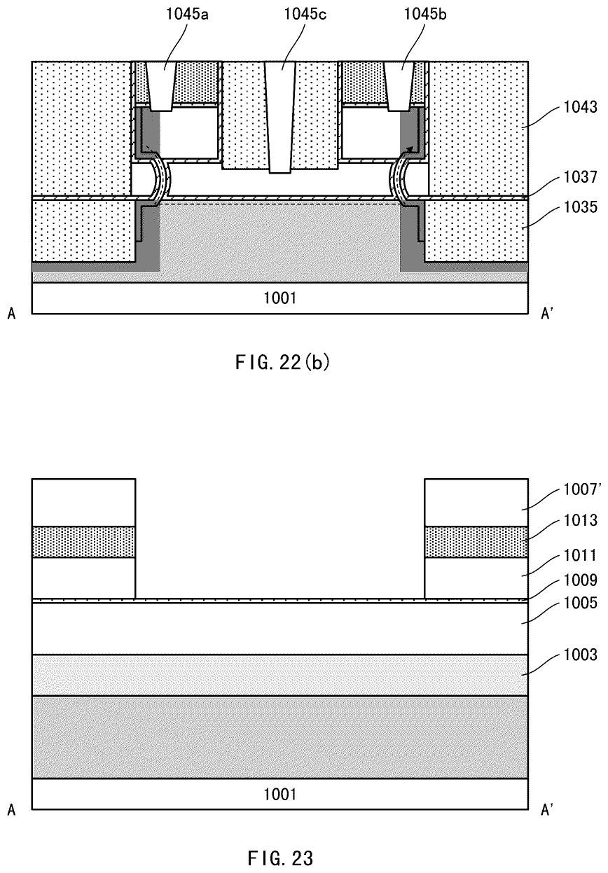

For example, as shown in FIGS. 22(a) and 22(b), a dielectric layer 1043 may be formed on the substrate by, for example, deposition followed by planarization. Then, a contact hole may be formed and filled with a conductive material such as metal to form a contact portion. For example, the contact portion may include a contact portion 1045c that penetrates the dielectric layer 1043 and is connected to the landing pad of the gate conductor layer, as well as contact portions 1045b and 1045a that penetrate the spacer 1017 and the etching stop layer 1009 and are connected to the source/drain portions.

As shown in FIGS. 22(a) and 22(b), a dashed line with an arrow is used to illustrate schematically the channel between the source/drain portions. As clearly shown in the figure, there is a channel formed in the vertical channel portion-lateral channel portion-vertical channel portion between the source/drain portions. The channel may also pass through the doping region (or source/drain portion) formed in the first material layer. In the case shown in FIG. 22(a), a length of the channel may be in a range of about 50 nm to 200 nm, for example. In the case shown in FIG. 22(b), a length of the channel may be in a range of about 5 nm to 30 nm, for example.

FIGS. 23 to 33(b) show schematic diagrams of some stages in a process of manufacturing a semiconductor device according to another embodiment of the present disclosure. In the following, the differences between above embodiments and this embodiment will be mainly described.

As described above in combination with FIGS. 1 and 2, the second material layer 1003 and the third material layer 1005 may be formed on the substrate 1001, and the etching stop layer 1009, the layer 1011 used for the mandrel pattern, and the hard mask layer 1013 may be formed on the third material layer 1005.

Next, the ridge may be patterned.

As shown in FIG. 23, a photoresist 1007′ may be formed on the hard mask layer 1013 and patterned to have an opening extending in the second direction. The opening has a certain width in the first direction. As described above in combination with FIG. 3, the photoresist 1007′ may be used as an etching mask for etching.

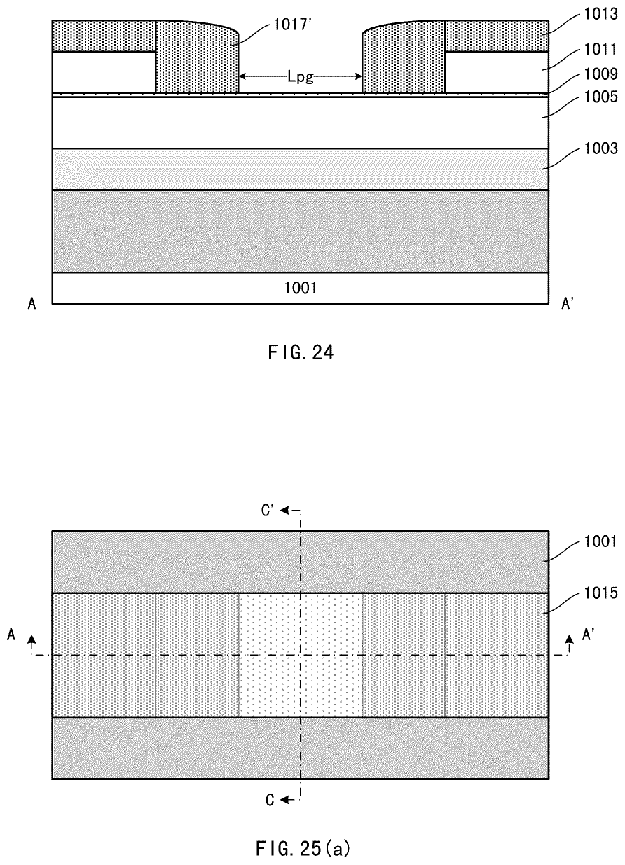

As shown in FIG. 24, as described above in combination with FIG. 4, the spacers 1017′ may be formed on sidewalls of the mandrel pattern 1011 at the opposite sides of the mandrel pattern 1011 in the first direction. The distance Lpg between the spacers 1017′ in the first direction may then define the gate length of the planar composition device.

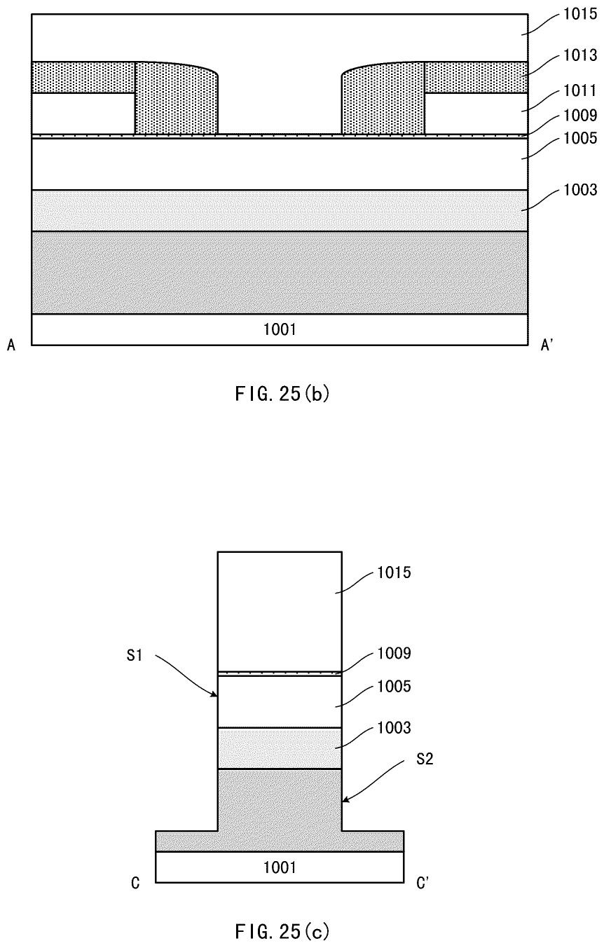

Similarly, the range of the ridge in the second direction may be defined. As shown in FIGS. 25(a) to 25(c), as described above in combination with FIGS. 5(a) to 5(c), the photoresist 1025 may be used as the etching mask for etching, so as to define the first sidewall S1 and the second sidewall S2.

As shown in FIGS. 26(a) to 26(d), as described above in combination with FIGS. 6(a) to 6(d), selective etching may be performed on the second material layer 1003 at the first sidewall S1 and the second sidewall S2, so as to recess the second material layer 1003 relatively. A first position retaining layer 1019 may be formed in the formed recess.

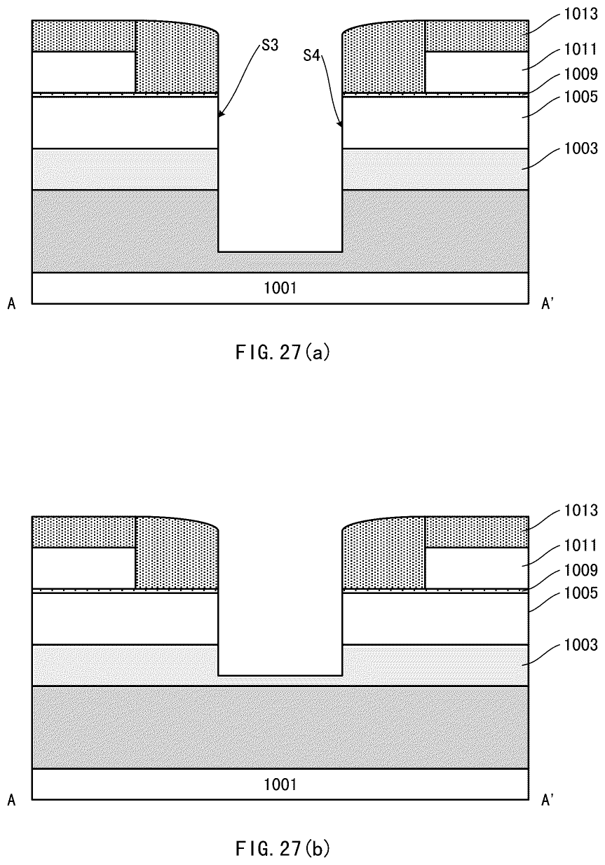

As shown in FIGS. 27(a) and 27(b), the hard mask layer 1013 and the spacer 1017 may be used as etching masks for etching, so as to define the third sidewall S3 and the fourth sidewall S4. In this embodiment, the third sidewall S3 and the fourth sidewall S4 may be similar to the fifth sidewall S5 and sixth sidewall S6 in previous embodiments. For example, the etching may be performed into the well region of the substrate 1001 (as described above in combination with FIG. 15(a)), or the etching may stop in the second material layer 1003 (as described above in combination with FIG. 15(b)). As described above, different etching stop positions may result in lateral channel portions in different shapes.

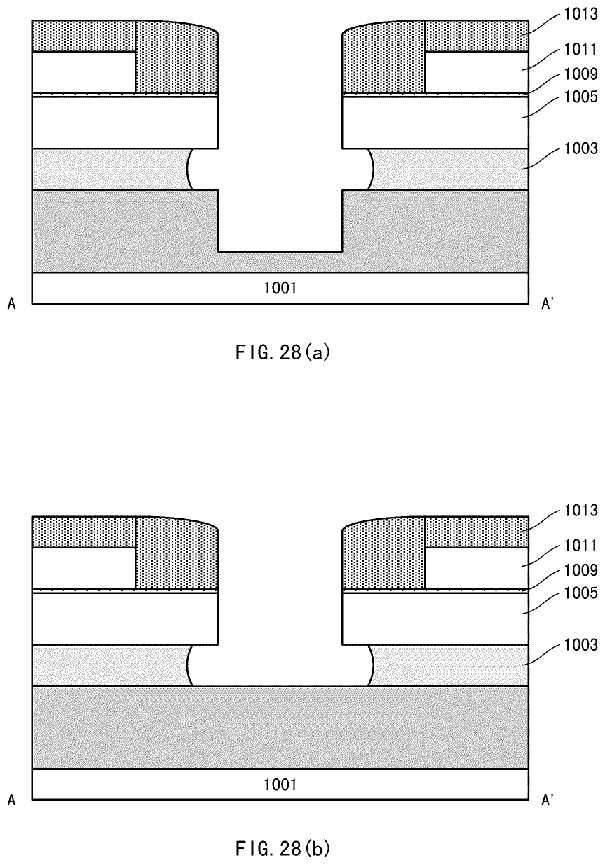

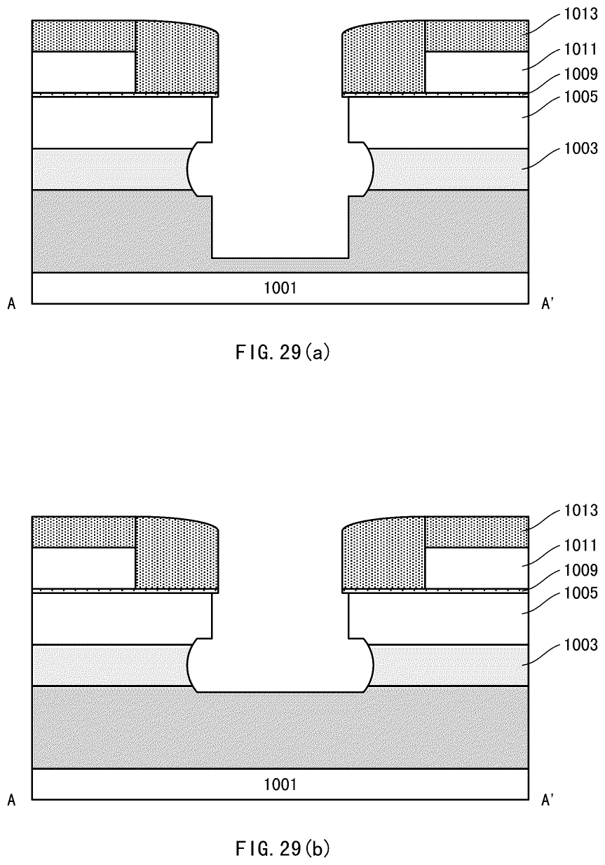

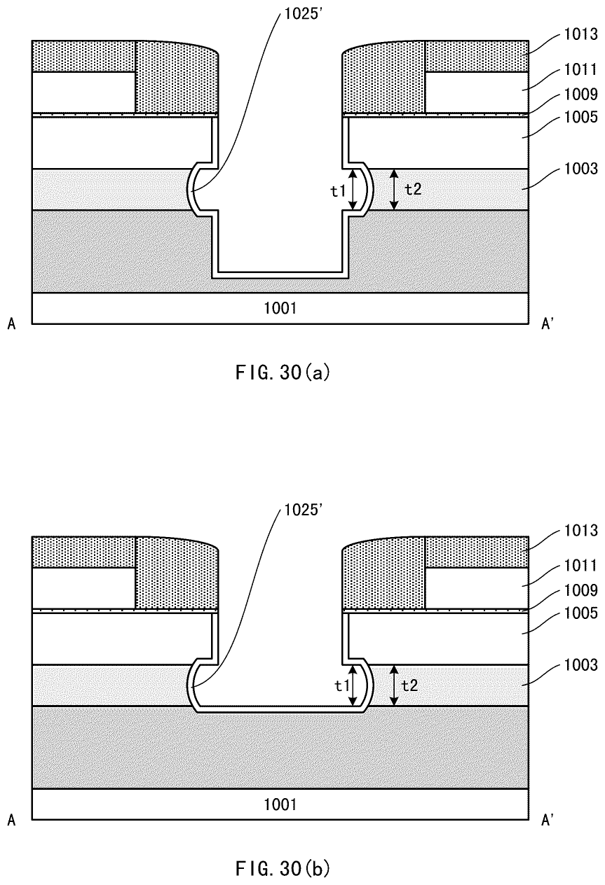

Similarly, a channel layer may be formed at the third sidewall S3 and the fourth sidewall S4. For example, as shown in FIGS. 28(a) and 28(b), as described above in combination with FIG. 8, selective etching may be performed on the second material layer 1003 to recess the second material layer 1003 relatively at the third sidewall S3 and the fourth sidewall S4. In addition, as shown in FIGS. 29(a) and 29(b), as described above in combination with FIG. 9, the ridge (specifically, the exposed surfaces of the first material layer, the second material layer, and the third material layer) may be etched back, so that the outer sidewall of the ridge is laterally recessed relative to the outer sidewall of the spacer 1017. Then, as shown in FIGS. 30(a) and 30(b), as described above in combination with FIG. 10, a channel layer 1025′ may be formed by selective epitaxial growth. Similarly, after growing the channel layer 1025′, the height t1 of the recess portion may be substantially the same as the thickness t2 of the second material layer 1003.

In this example, the channel layer includes a part extending between two vertical channel portions, which (and possibly, along with the adjacent substrate part) may define the lateral channel portion. As described above, the lateral channel portion may be doped through, for example, ion implantation, so as to adjust the threshold of the device.

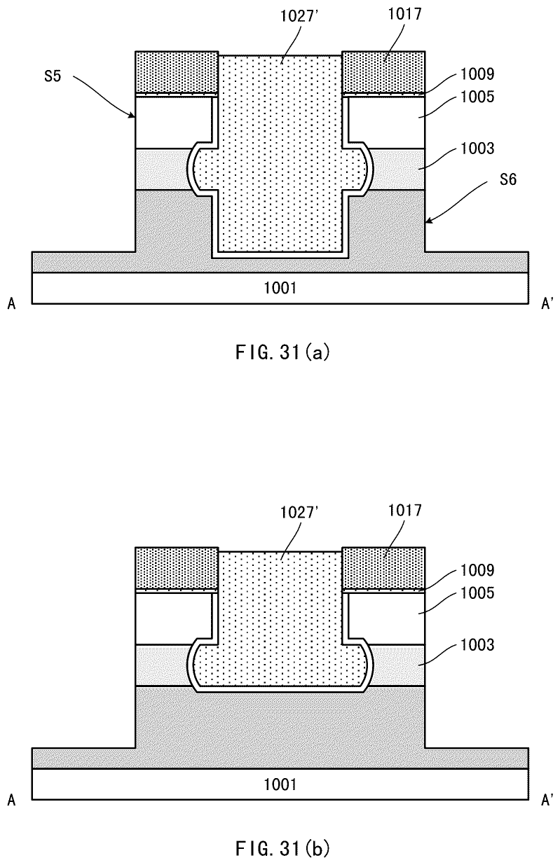

Similarly, a second position retaining layer may be formed at the third sidewall S3 and the fourth sidewall S4. Here, considering the subsequent process of forming the fifth and sixth sidewalls, the gap between the opposite spacers may be filled with the second position retaining layer. For example, as shown in FIGS. 31(a) and 31(b), an oxide may be deposited and planarized by, for example, CMP, to expose the mandrel pattern 1011. The mandrel pattern 1011 may be removed by selective etching. In this way, a pair of spacers 1017 extending opposite to each other is left on the ridge. The gap between such pair of spacers 1017 may be filled with the left oxide 1027′, and the left oxide 1027′ may occupy the recess portion (equivalent to the second position retaining layer) at the third sidewall S3 and the fourth sidewall S4. The spacer 1017 may be used as an etching mask for etching to define the fifth sidewall S5 and the sixth sidewall S6. In this embodiment, the fifth sidewall S5 and the sixth sidewall S6 may be similar to the third sidewall S3 and the fourth sidewall S4 in previous embodiments. The second material layer may be exposed at the fifth sidewall S5 and the sixth sidewall S6.

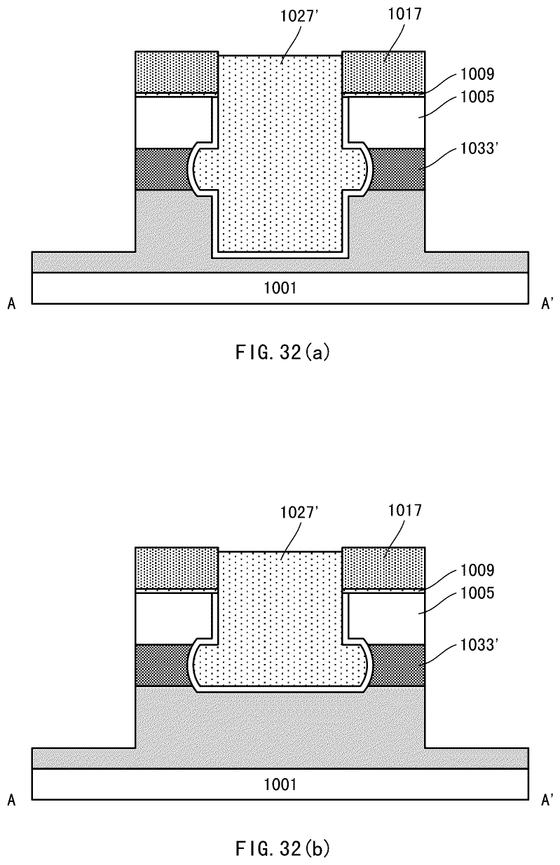

As shown in FIGS. 32(a) and 32(b), the second material layer may be removed by selective etching, and a third position retaining layer 1033′ may be formed in the gap left due to the removal of the second material layer.

As described above in combination with FIGS. 12 and 13, a solid-state dopant source layer may be formed. A dopant in the solid-state dopant source layer may be driven into the third material layer through annealing to form the source/drain portion.

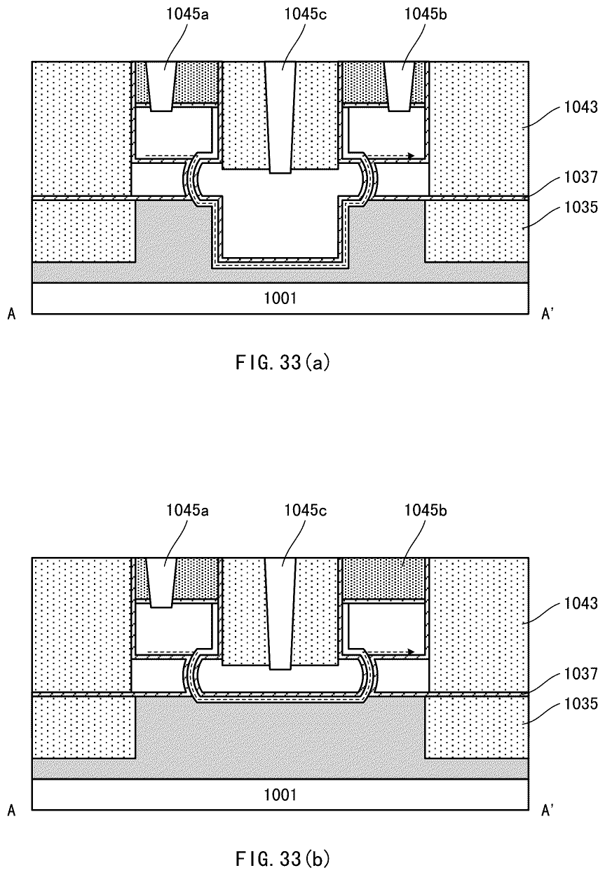

As shown in FIGS. 33(a) and 33(b), an isolation layer 1035 may be formed by deposition, planarization, followed by etching back. As described above in combination with FIG. 18, a part of the isolation layer 1035 may be removed to expose the lateral channel portion. Afterwards, the position retaining layer may be removed and the gate stack may be formed on the isolation layer 1035.

As shown in FIGS. 33(a) and 33(b), a dashed line with an arrow is used to illustrate schematically the channel between the source/drain portions. As clearly shown in the figure, there is a channel formed in the vertical channel portion-lateral channel portion-vertical channel portion between the source/drain portions. It should be pointed out that the figure shows that the channel has a lateral extension part in the third material layer, because in the case of forming the source/drain portions through diffusion doping, the source/drain portions may be formed in the parts of the third material layer close to the fifth sidewall S5 and the sixth sidewall S6 (please refer to the source/drain portions shaded in FIG. 13).

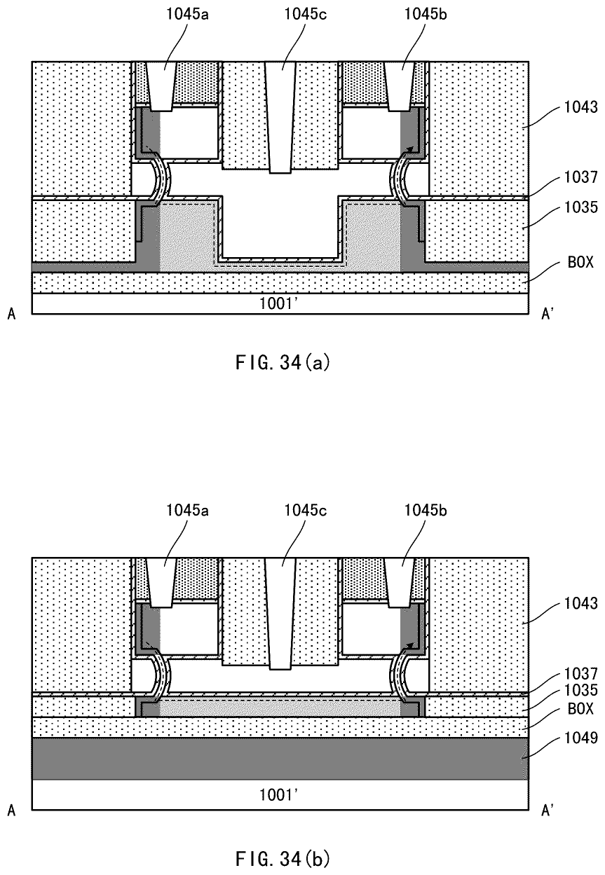

FIGS. 34(a) and 34(b) show schematic diagrams of semiconductor devices according to embodiments of the present disclosure.

Embodiments shown in FIGS. 34(a) and 34(b) are substantially the same as previously described embodiments, except that the device is provided on a semiconductor on insulator (SOI) substrate. More specifically, the SOI substrate may include a buried insulation layer BOX and an SOI layer on the BOX. The first material layer described above may be provided by either the SOI layer or an epitaxial layer on the SOI layer.

In this example, especially when the lateral channel portion is substantially flat, a back gate 1049 may be formed in the substrate 1001′, for example, through the well region. The back gate 1049 is opposite to the lateral channel portion via the buried insulation layer BOX, and may exert influence on the lateral channel portion.

The semiconductor device according to embodiments of the present disclosure may be applied to various electronic apparatuses. For example, an integrated circuit (IC) may be formed based on such semiconductor devices, and an electronic apparatus may be constructed in this way. Therefore, the present disclosure further provides an electronic apparatus including the semiconductor device described above. The electronic apparatus may further include components such as a display screen cooperating with the integrated circuit and a wireless transceiver cooperating with the integrated circuit. The electronic apparatus may include, for example, a smart phone, a computer, a tablet computer (PC), an artificial intelligence apparatus, a wearable apparatus, a mobile power supply, an automotive electronic apparatus, communication apparatus, or an Internet of Things (IoT) apparatus.

According to embodiments of the present disclosure, a method of manufacturing a system on chip (SoC) is further provided. This method may include the above-described method. Specifically, a variety of devices may be integrated on the chip, at least some of which are manufactured according to the method of the present disclosure.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may further design a method that is not completely the same as the method described above. In addition, although the various embodiments are described above separately, this does not mean that the measures in the various embodiments may not be advantageously used in combination.

Embodiments of the present disclosure have been described above. However, these embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

1. A semiconductor device, comprising:
a semiconductor base on a substrate;
a first vertical channel portion and a second vertical channel portion on the semiconductor base, wherein the first vertical channel portion and the second vertical channel portion are vertical relative to the substrate, protrude from the semiconductor base, are spaced apart from each other in a first direction, and are self-aligned with each other, and the semiconductor base extends continuously between the first vertical channel portion and the second vertical channel portion;
a first source/drain portion and a second source/drain portion on the first vertical channel portion and the second vertical channel portion, respectively; and
a gate stack, wherein the gate stack is at least partially provided on the first vertical channel portion, the semiconductor base, and the second vertical channel portion, so as to define a continuous channel between the first source/drain portion and the second source/drain portion.

2. The semiconductor device according to claim 1, wherein each of the first vertical channel portion and the second vertical channel portion comprises a semiconductor nanosheet or a semiconductor nanowire.

3. The semiconductor device according to claim 2, wherein the first vertical channel portion and the second vertical channel portion are curved.

4. The semiconductor device according to claim 3, wherein a sign of a curvature of the first vertical channel portion is opposite to a sign of a curvature of the second vertical channel portion.

5. The semiconductor device according to claim 3, wherein the first vertical channel portion is substantially symmetrical with the second vertical channel portion.

6. The semiconductor device according to claim 3, wherein each of the first vertical channel portion and the second vertical channel portion has a C-shaped cross-section, and
wherein an opening of the C-shaped cross-section of the first vertical channel portion and an opening of the C-shaped cross-section of the second vertical channel portion are facing away from each other; or an opening of the C-shaped cross-section of the first vertical channel portion and an opening of the C-shaped cross-section of the second vertical channel portion are facing each other.

7. The semiconductor device according to claim 1, wherein the gate stack surrounds an outer periphery of each of the first vertical channel portion and the second vertical channel portion.

8. The semiconductor device according to claim 1, wherein the first vertical channel portion is substantially coplanar with the second vertical channel portion.

9. The semiconductor device according to claim 1, wherein the semiconductor base is directly provided on the substrate.

10. The semiconductor device according to claim 1, wherein the substrate comprises a buried insulation layer, and the semiconductor base is provided on the buried insulation layer.

11. The semiconductor device according to claim 10, further comprising:
a back gate below the buried insulation layer in the substrate, wherein the back gate is opposite to the semiconductor base via the buried insulation layer.

12. The semiconductor device according to claim 1, wherein the semiconductor base comprises a recess between the first vertical channel portion and the second vertical channel portion.

13. The semiconductor device according to claim 12, wherein a length of the channel is in a range of about 50 nm to 200 nm.

14. The semiconductor device according to claim 1, wherein the semiconductor base has a substantially flat upper surface between the first vertical channel portion and the second vertical channel portion.

15. The semiconductor device according to claim 14, wherein a length of the channel is in a range of about 5 nm to 30 nm.

16. The semiconductor device according to claim 1, wherein a part of the gate stack adjacent to the first vertical channel portion and a part of the gate stack adjacent to the second vertical channel portion are self-aligned with the first vertical channel portion and the second vertical channel portion, respectively.

17. The semiconductor device according to claim 1, wherein the first source/drain portion is substantially coplanar with the second source/drain portion.

18. The semiconductor device according to claim 1, wherein the first source/drain portion, the first vertical channel portion, and the semiconductor base are self-aligned in a vertical direction, and the second source/drain portion, the second vertical channel portion, and the semiconductor base are self-aligned in the vertical direction.

19. The semiconductor device according to claim 1, wherein the semiconductor base comprises a first semiconductor layer on the substrate, and the first source/drain portion and the second source/drain portion are provided in a second semiconductor layer on the first vertical channel portion and the second vertical channel portion.

20. The semiconductor device according to claim 19, wherein the first source/drain portion is a doping region in the second semiconductor layer on the first vertical channel portion, the second source/drain portion is a doping region in the second semiconductor layer on the second vertical channel portion, and the first semiconductor layer comprises a doping region substantially aligned with the first source/drain portion in a vertical direction and a doping region substantially aligned with the second source/drain portion in the vertical direction.

21. The semiconductor device according to claim 1, further comprising:
a third source/drain portion below the first vertical channel portion in the semiconductor base and a fourth source/drain portion below the second vertical channel portion in the semiconductor base,
wherein the channel extends continuously between the first source/drain portion and the second source/drain portion and passes through the third source/drain portion and the fourth source/drain portion.

22. A method of manufacturing a semiconductor device, comprising:
providing, on a substrate, a stack of a first material layer, a second material layer, and a third material layer;
patterning the stack as a ridge, wherein the ridge comprises first and second sidewalls extending in a first direction and opposite in a second direction intersecting with the first direction, as well as third and fourth sidewalls extending in the second direction and opposite in the first direction;
recessing, at the third and fourth sidewalls, a sidewall of the second material layer laterally relative to a sidewall of the first material layer and a sidewall of the third material layer, so as to define a first recess portion;
forming a channel layer on a surface of the second material layer exposed by the first recess portion;
forming a first position retaining layer in a remaining space of the first recess portion;
further patterning the ridge to form fifth and sixth sidewalls extending in the second direction and opposite in the first direction, so that the second material layer is exposed at the fifth and sixth sidewalls, wherein the first material layer extends continuously in the first direction between the channel layer formed at the third sidewall and the channel layer formed at the fourth sidewall;
removing the second material layer at the fifth and sixth sidewalls;
forming a second position retaining layer in a space released due to a removal of the second material layer;
forming a source/drain portion in the third material layer;
forming an isolation layer on the substrate, wherein the isolation layer exposes a part of the first material layer extending between the channel layer formed at the third sidewall and the channel layer formed at the fourth sidewall;
removing the first position retaining layer and the second position retaining layer; and
forming a gate stack on the isolation layer, wherein the gate stack has a part embedded in a space left due to a removal of the first position retaining layer and the second position retaining layer.

23. The method according to claim 22, further comprising:
recessing, at the first and second sidewalls, the sidewall of the second material layer laterally relative to the sidewall of the first material layer and the sidewall of the third material layer, so as to define a third recess portion; and
forming a third position retaining layer in the third recess portion,
wherein the removing the first position retaining layer and the second position retaining layer further comprises: removing the third position retaining layer, and
wherein the forming the gate stack comprises: forming a gate dielectric layer and a gate conductor layer, wherein the gate dielectric layer and the gate conductor layer enter a space released due to a removal of the first position retaining layer, the second position retaining layer, and the third position retaining layer.

24. The method according to claim 22, wherein the channel layer is formed through epitaxial growth.

25. The method according to claim 22, wherein the sidewall of the second material layer is recessed by using isotropic etching.

26. The method according to claim 22, wherein
the third sidewall and the fourth sidewall are located between the fifth sidewall and the sixth sidewall, and an opening of the first recess portion at the third sidewall and an opening of the first recess portion at the fourth sidewall are facing each other; or
the fifth sidewall and the sixth sidewall are located between the third sidewall and the fourth sidewall, and an opening of the first recess portion at the third sidewall and an opening of the first recess portion at the fourth sidewall are facing away from each other.

27. The method according to claim 22, wherein
the gate stack defines a continuous extending channel in the channel layer at the third sidewall, the first material layer, and the channel layer at the fourth sidewall, and
the first material layer comprises a recess between the channel layer at the third sidewall and the channel layer at the fourth sidewall, and a length of the channel is in a range of about 50 nm to 200 nm; or, the first material layer has a substantially flat upper surface between the channel layer at the third sidewall and the channel layer at the fourth sidewall, and a length of the channel is in a range of about 5 nm to 30 nm.

28. The method according to claim 22, wherein the substrate comprises a buried insulation layer, and the first material layer is provided on the buried insulation layer.

29. The method according to claim 28, further comprising:
forming, in the substrate, a back gate below the buried insulation layer.

30. The method according to claim 22, wherein the first recess portion is in a curved shape.

31. The method according to claim 30, wherein a sign of a curvature of the first recess portion at the first sidewall is opposite to a sign of a curvature of the first recess portion at the second sidewall.

32. The method according to claim 22, further comprising:
forming a source/drain portion at a position in the first material layer where the source/drain portion in the first material layer is substantially aligned with the source/drain portion formed in the third material layer in a vertical direction.

33. An electronic apparatus, comprising the semiconductor device according to claim 1.

34. The electronic apparatus according to claim 33, wherein the electronic apparatus comprises: a smart phone, a personal computer, a tablet computer, an artificial intelligence apparatus, a wearable apparatus, a mobile power supply, an automotive electronic apparatus, a communication apparatus, or an Internet of Things apparatus.
